(19) United States
(12) Patent Application Publication
(10) Pub. No.: US 2014/0054070 A1
(43) Pub. Date: Feb. 27, 2014

(54) ELECTROCONDUCTIVE SHEET AND TOUCH PANEL

(71) Applicant: FUJIFILM CORPORATION, Tokyo (JP)

(72) Inventor: Akira ICHIKI, Ashigarakami-gun (JP)

(73) Assignee: FUJIFILM CORPORATION, Tokyo (JP)

(21) Appl. No.: 13/969,355

(22) Filed: Aug. 16, 2013

Related U.S. Application Data
(63) Continuation of application No. PCT/JP2012/053860, filed on Feb. 17, 2012.

(30) Foreign Application Priority Data
Feb. 18, 2011 (JP) 2011-033238

(51) Int. Cl. H05K 1/02

(52) U.S. Cl. CPC H05K 1/0274
USPC 174/253; 174/250

(57) ABSTRACT

An electroconductive sheet and a touch panel, wherein the electroconductive sheet has a first electroconductive section and a second electroconductive section; the first electroconductive section has a plurality of first electroconductive patterns arrayed in one direction and to which a plurality of first electrodes, respectively, are connected; the second electroconductive section has a plurality of second electroconductive patterns arrayed in a direction orthogonal to the arrayed direction of the first electroconductive patterns and to which a plurality of second electrodes, respectively, are connected; and the electroconductive sheet has dummy electrodes disposed between the first electrodes and the second electrodes, and other dummy electrodes disposed in portions corresponding to the second electrodes.

### CROSS-REFERENCE TO RELATED APPLICATIONS AND PRIORITY CLAIMS

This application is a Continuation of International Application No. PCT/JP2012/053860 filed on Feb. 17, 2012, which was published under PCT Article 21(2) in Japanese, which is based upon and claims the benefit of priority from Japanese Patent Application No. 2011-033238 filed on Feb. 18, 2011, the contents all of which are incorporated herein by reference.

### TECHNICAL FIELD

The present invention relates to a conductive sheet and a touch panel, for example suitable for use in a projected capacitive touch panel.

### BACKGROUND ART

Touch panels have attracted much attention in recent years. Though the touch panel has currently been used mainly in small devices such as PDAs (personal digital assistants) and mobile phones, it is expected to be used in large devices such as personal computer displays.

A conventional electrode for the touch panel is composed of ITO (indium tin oxide) and therefore has a high resistance. Thus, when the conventional electrode is used in the large device in the above future trend, the large-sized touch panel has a low current transfer rate between the electrodes, and thereby exhibits a low response speed (a long time between finger contact and touch position detection).

A large number of lattices made of thin wires of metal (thin metal wires) can be arranged to form an electrode with a lowered surface resistance. Touch panels using the electrode of the thin metal wires are known from Japanese Laid-Open Patent Publication No. 05-224818, U.S. Pat. No. 5,113,041, International Patent Publication No. 1995/27334, US Patent Application Publication No. 2004/0239650, U.S. Pat. No. 7,202,859, International Patent Publication No. 1997/18508, Japanese Laid-Open Patent Publication No. 2003-099185, etc.

Projected capacitive touch panels have widely been used in PDAs, mobile phones, etc. In such a touch panel, X electrodes and Y electrodes are alternately arranged with an insulator interposed therebetween. Therefore, above the insulator (around the input operation surface), large contrast difference is observed at the boundaries between portions having the X electrodes and portions not having the X electrodes. Similarly, below the insulator (around the display panel), large contrast difference is observed at the boundaries between portions having the Y electrodes and portions not having the Y electrodes. Consequently, the electrodes are highly visible to the outside disadvantageously.

A method using dummy electrodes arranged between the electrodes is known as a measure against this problem (see Japanese Laid-Open Patent Publication Nos. 2008-129708 and 2010-039537).

### SUMMARY OF INVENTION

The touch panel electrode of the thin metal wires has problems with transparency and visibility because the thin metal wires are composed of an opaque material. In the case of using a conductive sheet containing the thin metal wire electrode on a display device, the conductive sheet is required to have the following two preferred visibility characteristics. The first characteristic is: when the display device is turned on to display an image, the metal wires are hardly visible, the conductive sheet exhibits a high visible light transmittance, and noise such as moire is hardly generated due to light interference between a period of pixels in the display device (such as a black matrix pattern in a liquid crystal display) and a conductive pattern. The second characteristic is: when the display device is turned off to show a black screen and is observed under an outside light such as a fluorescent light, sunlight, or LED light, the thin metal wires are hardly visible.

In general, the visibility can be improved by reducing the line width of the thin metal wires. However, the electrode containing the thin metal wires with the reduced line width disadvantageously has an increased resistance, which deteriorates the touch position detection sensitivity. Therefore, it is necessary to optimize the shapes of the conductive pattern and the thin metal wire pattern.

In view of the above problems, an object of the present invention is to provide a conductive sheet and a touch panel, which can have an electrode containing a pattern of less-visible, thin, metal wires with a high transparency.

[1] A conductive sheet according to a first aspect of the present invention is used on a display panel of a display device, and comprises a first conductive part disposed closer to an input operation surface and a second conductive part disposed closer to the display panel. The first and second conductive parts overlap with each other. The first conductive part contains a plurality of first conductive patterns, which are arranged in one direction and each connected to a plurality of first electrodes. The second conductive part contains a plurality of second conductive patterns, which are arranged in a direction perpendicular to the one direction of the first conductive patterns and each connected to a plurality of second electrodes. The first conductive part and/or the second conductive part contain dummy electrodes composed of thin metal wires disposed between the first and second electrodes, and the first conductive part further contains additional dummy electrodes composed of the thin metal wires disposed in positions corresponding to the second electrodes.

In a case where the additional dummy electrodes are not formed in the touch panel conductive sheet, the light transmittance difference between a portion corresponding to the first electrode and a portion corresponding to the second electrode is increased, deteriorating the visibility (to make the first or second electrode highly visible). Thus, in the first aspect, the additional dummy electrodes are formed, whereby the portions corresponding to first and second electrodes have uniform light transmittance to improve the visibility.

Consequently, even in the case of using the patterns of the thin metal wires in the electrodes of the touch panel, the conductive sheet can have a high transparency.

[2] In view of achieving the uniform light transmittance in the portions corresponding to first and second electrodes, it is preferred that the difference in light shielding ratio between the first electrodes and overlaps of the second electrodes and the additional dummy electrodes is 20% or less.

[3] It is further preferred that the difference in light shielding ratio between the first electrodes and overlaps of the second electrodes and the additional dummy electrodes is 10% or less.

[4] When the number of the additional dummy electrodes is excessively increased, the conductivity of the second electrodes may be lowered in view of achieving the uniform light transmittance. Thus, it is preferred that the light shielding ratio of the additional dummy electrodes is 50% or less of the light shielding ratio of the first electrodes.

[5] It is further preferred that the light shielding ratio of the additional dummy electrodes is 25% or less of the light shielding ratio of the first electrodes.

[6] In the first aspect, the additional dummy electrodes composed of the thin metal wires disposed in the positions corresponding to the second electrodes and the second electrodes in the second conductive part are combined to form lattice patterns. In this case, the first and second electrodes are less visible, whereby the visibility is improved.

[7] In the first aspect, the second electrodes are composed of the thin metal wires arranged in a mesh pattern.

[8] In this case, the first electrodes may each contain a combination of a plurality of first small lattices, the second electrodes may each contain a combination of a plurality of second small lattices larger than the first small lattices, the second small lattices may each have a length component, and a length of the length component may be a real-number multiple of a side length of the first small lattice.

[9] In the first aspect, the additional dummy electrodes disposed in the positions corresponding to the second electrodes are composed of the thin metal wires having a straight line shape.

[10] In this case, the first electrodes may each contain a combination of a plurality of first small lattices, and the length of the thin metal wire having the straight line shape in the additional dummy electrodes is a real-number multiple of a side length of the first small lattice.

[11] In the first aspect, the additional dummy electrodes disposed in the positions corresponding to the second electrodes are composed of the thin metal wires arranged in a mesh pattern.

[12] In this case, the first electrodes may each contain a combination of a plurality of first small lattices, the additional dummy electrodes may each contain a combination of a plurality of second small lattices larger than the first small lattices, the second small lattices may each have a length component, and a length of the length component may be a real-number multiple of a side length of the first small lattice.

[13] In the first aspect, the conductive sheet may further comprise a substrate, and the first and second conductive parts may be arranged facing each other with the substrate interposed therebetween.

[14] In the first aspect, the first conductive part may be formed on one main surface of the substrate, and the second conductive part may be formed on the other main surface of the substrate.

[15] In the first aspect, the conductive sheet may further comprises a substrate, the first and second conductive parts may be arranged facing each other with the substrate interposed therebetween, the first and second electrodes may each have a mesh pattern, auxiliary patterns of the additional dummy electrodes composed of the thin metal wires may be disposed between the first electrodes in an area corresponding to the second electrodes, the second electrodes may be arranged adjacent to the first electrodes as viewed from above, the second electrodes may overlap with the auxiliary patterns to form combined patterns, and the combined patterns may each contain a combination of mesh shapes.

[16] In this case, the first electrodes may each contain a first large lattice containing a combination of a plurality of first small lattices, the second electrodes may each contain a second large lattice containing a combination of a plurality of second small lattices larger than the first small lattices, and the combined patterns may each contain a combination of two or more first small lattices.

In this case, the boundaries between the first and second large lattices are less visible, and the visibility is improved.

[17] In the first aspect, the occupation area of the first conductive patterns is larger than the occupation area of the second conductive patterns. In this case, the surface resistance of the first conductive patterns can be lowered, and a noise impact of an electromagnetic wave can be reduced.

[18] In this case, it is preferred that the thin metal wires have a line width of 6 μm or less and a line pitch of 200 μm or more and 500 μm or less, or alternatively the thin metal wires have a line width of more than 6 μm but at most 7 μm and a line pitch of 300 μm or more and 400 μm or less.

[19] It is further preferred that the thin metal wires have a line width of 5 μm or less and a line pitch of 200 μm or more and 400 μm or less, or alternatively the thin metal wires have a line width of more than 5 μm but at most 7 μm and a line pitch of 300 μm or more and 400 μm or less.

[20] It is preferred that when the first conductive patterns have an occupation area A1 and the second conductive patterns have an occupation area A2, the conductive sheet satisfies the condition of 1<A1/A2≦20.

[21] It is further preferred that the conductive sheet satisfies the condition of 1<A1/A2≦10.

[22] It is particularly preferred that the conductive sheet satisfies the condition of 2≦A1/A2≦10.

[23] A touch panel comprises a conductive sheet, which is used on a display panel of a display device, and the conductive sheet has a first conductive part disposed closer to an input operation surface and a second conductive part disposed closer to the display panel. The first and second conductive parts overlap with each other. The first conductive part contains a plurality of first conductive patterns, which are arranged in one direction and each connected to a plurality of first electrodes. The second conductive part contains a plurality of second conductive patterns, which are arranged in a direction perpendicular to the one direction of the first conductive patterns and each connected to a plurality of second electrodes. The first conductive part and/or the second conductive part contain dummy electrodes disposed between the first and second electrodes, and the first conductive part contains additional dummy electrodes disposed in positions corresponding to the second electrodes.

In the touch panel, even in the case of using the patterns of the thin metal wires in the electrodes, the conductive sheet can have a high transparency.

As described above, the conductive sheet and the touch panel of the present invention can have the electrodes containing the patterns of less-visible, thin, metal wires and can exhibit a high transparency.

### BRIEF DESCRIPTION OF DRAWINGS

FIG. 1 is an exploded perspective view of a touch panel according to an embodiment of the present invention;

FIG. 2 is a partially omitted, exploded perspective view of a conductive sheet stack;

FIG. 3A is a partially omitted, cross-sectional view of an example of the conductive sheet stack, and FIG. 3B is a partially omitted, cross-sectional view of another example of the conductive sheet stack;

FIG. 4 is a plan view of a pattern example of first conductive patterns formed on a first conductive sheet;

FIG. 5 is a plan view of a pattern example of second conductive patterns formed on a second conductive sheet;

FIG. 6 is a partially omitted, plan view of the conductive sheet stack formed by combining the first and second conductive sheets;

FIG. 7 is an explanatory view of one line formed by first and third auxiliary wires;

FIG. 8 is a plan view of a pattern example of first conductive patterns according to a first variant example;

FIG. 9 is a plan view of a pattern example of second conductive patterns according to the first variant example;

FIG. 10 is a partially omitted, plan view of a conductive sheet stack formed by combining a first conductive sheet having the first conductive patterns of the first variant example and a second conductive sheet having the second conductive patterns of the first variant example;

FIG. 11 is a plan view of a pattern example of first conductive patterns according to a second variant example;

FIG. 12 is a plan view of a pattern example of second conductive patterns according to the second variant example;

FIG. 13 is a flow chart of a method for producing the conductive sheet stack of this embodiment;

FIG. 14A is a partially omitted, cross-sectional of a produced photosensitive material, and FIG. 14B is an explanatory view for illustrating simultaneous both-side exposure of the photosensitive material; and

FIG. 15 is an explanatory view for illustrating first and second exposure treatments performed such that a light incident on a first photosensitive layer does not reach a second photosensitive layer and a light incident on the second photosensitive layer does not reach the first photosensitive layer.

### DESCRIPTION OF EMBODIMENTS

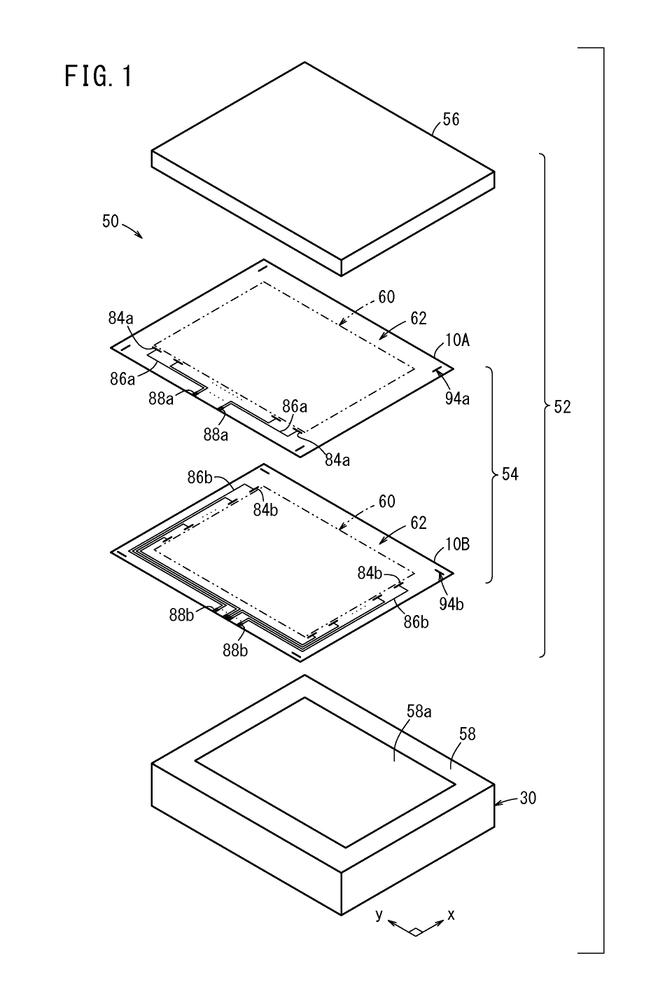

Several embodiments of the conductive sheet and the touch panel of the present invention will be described below with reference to FIGS. 1 to 15. It should be noted that, in this description, a numeric range of “A to B” includes both the numeric values A and B as the lower limit and upper limit values.

A touch panel having a conductive sheet according to an embodiment of the present invention will be described below with reference to FIG. 1.

The touch panel 50 has a sensor body 52 and a control circuit such as an integrated circuit (not shown). The sensor body 52 contains a conductive sheet stack 54 and thereon a protective layer 56, and the conductive sheet stack 54 is formed by stacking a first conductive sheet 10A and a second conductive sheet 10B to be hereinafter described. The conductive sheet stack 54 and the protective layer 56 can be disposed on a display panel 58 of a display device 30 such as a liquid crystal display. As viewed from above, the sensor body 52 has a sensing region 60 corresponding to a display screen 58a of the display panel 58 and a terminal wiring region 62 (a so-called frame) corresponding to the periphery of the display panel 58.

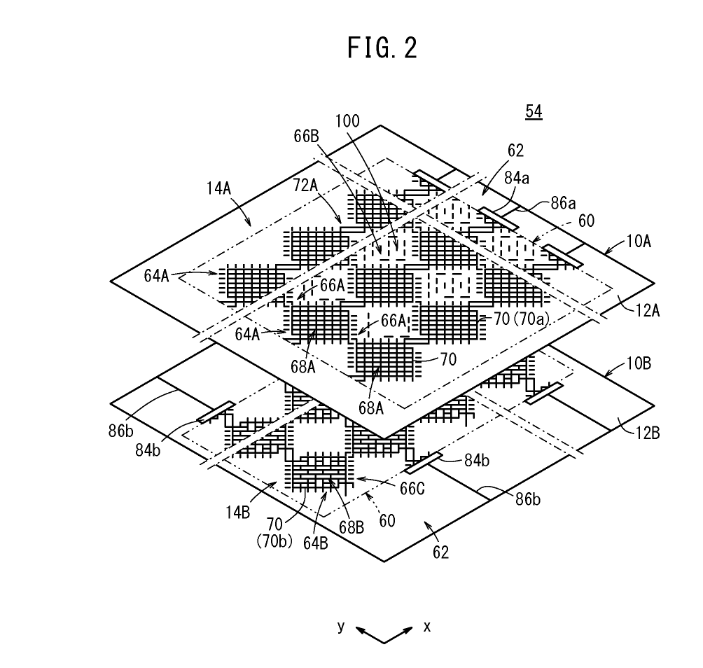

As shown in FIGS. 2, 3A, and 4, the first conductive sheet 10A has a first conductive part 14A formed on one main surface of a first transparent substrate 12A. The first conductive part 14A contains two or more first conductive patterns 64A and first auxiliary patterns 66A (dummy electrodes). The first conductive patterns 64A extend in a first direction (an x direction), are arranged in a second direction (the y direction) perpendicular to the first direction, each contain a large number of small lattices 70, and are composed of thin metal wires 16. The first auxiliary patterns 66A are arranged around the first conductive patterns 64A and are composed of the thin metal wires 16. For example, the thin metal wires 16 contain gold (Au), silver (Ag), or copper (Cu).

The first conductive pattern 64A contains two or more first large lattices 68A. The first large lattices 68A are connected in series in the first direction, and each contain a combination of two or more small lattices 70. The above first auxiliary pattern 66A is formed around a side of the first large lattice 68A and is not connected to the first large lattice 68A. In this example, the small lattice 70 has a smallest rhombus (or square) shape. The x direction corresponds to the horizontal or vertical direction of the touch panel 50 or the display panel 58 equipped therewith (see FIG. 1).

The first conductive pattern 64A is not limited to the example using the first large lattices 68A. For example, the first conductive pattern 64A may be formed such that a large number of the small lattices 70 are arranged to form a strip-shaped mesh pattern, and a plurality of the strip-shaped mesh patterns are arranged in parallel and are isolated from each other by insulations. For example, two or more of strip-shaped first conductive patterns 64A may each extend from a terminal in the x direction and may be arranged in the y direction.

The line width of the small lattice 70 (the thin metal wire 16) may be 30 μm or less. In the touch panel 50, the line width of the thin metal wire 16 is preferably 0.1 μm or more and 15 μm or less, more preferably 1 μm or more and 9 μm or less, further preferably 2 μm or more and 7 μm or less. The side length of the small lattice 70 may be selected within a range of 100 to 400 μm.

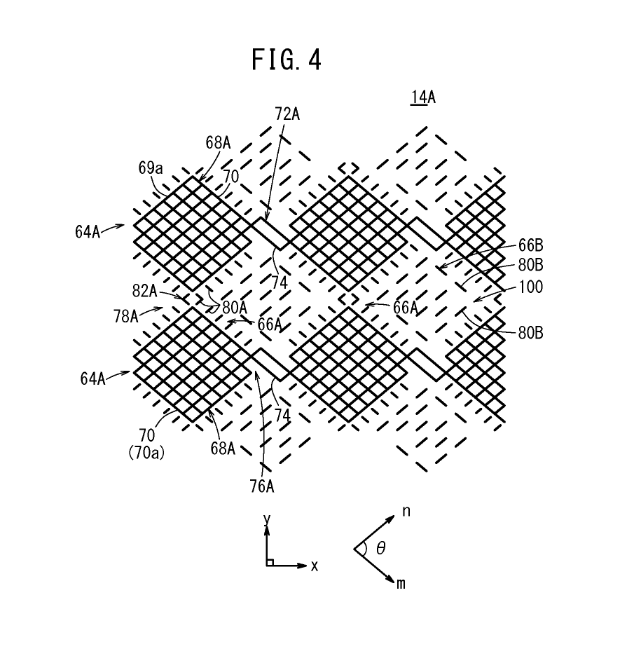

In the case of using the first large lattices 68A in the first conductive patterns 64A, for example, as shown in FIG. 4, first connections 72A composed of the thin metal wires 16 are formed between the first large lattices 68A, and each adjacent two of the first large lattices 68A are electrically connected by the first connection 72A. The first connection 72A contains a medium lattice 74, and the size of the medium lattice 74 corresponds to the total size of p small lattices 70 (in which p is a real number larger than 1) arranged in a third direction (an m direction). A first absent portion 76A (a portion provided by removing one side from the small lattice 70) is formed between the medium lattice 74 and a side of the first large lattice 68A extending along a fourth direction (an n direction). In the example of FIG. 4, the size of the medium lattice 74 corresponds to the total size of three small lattices 70 arranged in the third direction. The angle θ between the third and fourth directions may be appropriately selected within a range of 60° to 120°. Further, the first conductive part 14A contains second auxiliary patterns 66B composed of the thin metal wires 16 (additional dummy electrodes) in blank areas 100 (light-transmitting areas) between the first large lattices 68A. The blank area 100 has a size approximately equal to a second large lattice 68B to be hereinafter described.

An electrically isolated first insulation 78A is disposed between the adjacent first conductive patterns 64A.

The first auxiliary pattern 66A contains a plurality of first auxiliary wires 80A (having an axis direction parallel to the fourth direction) arranged along the side of the first large lattice 68A parallel to the third direction, a plurality of first auxiliary wires 80A (having an axis direction parallel to the third direction) arranged along the side of the first large lattice 68A parallel to the fourth direction, and two L-shaped patterns 82A arranged facing each other. Each of the L-shaped patterns 82A is formed by combining two first auxiliary wires 80A into an L shape in the first insulation 78A. The first auxiliary wires 80A and the L-shaped patterns 82A may have a smaller length in the longitudinal direction and thus a dot shape.

The second auxiliary pattern 66B contains second auxiliary wires 80B having an axis direction parallel to the third direction and/or second auxiliary wires 80B having an axis direction parallel to the fourth direction. Of course, the second auxiliary pattern 66B may contain an L-shaped pattern formed by combining two second auxiliary wires 80B into an L shape. The second auxiliary wires 80B and the L-shaped patterns may have a smaller length in the longitudinal direction and thus a dot shape.

As shown in FIG. 2, in the first conductive sheet 10A having the above structure, in one end of each first conductive pattern 64A, the first connection 72A is not formed on the open end of the first large lattice 68A. In the other end of the first conductive pattern 64A, the end of the first large lattice 68A is electrically connected to a first terminal wiring pattern 86a composed of the thin metal wire 16 by a first wire connection 84a.

Thus, in the first conductive sheet 10A used in the touch panel 50, a large number of the above first conductive patterns 64A are arranged in the sensing region 60, and a plurality of the first terminal wiring patterns 86a extend from the first wire connections 84a in the terminal wiring region 62.

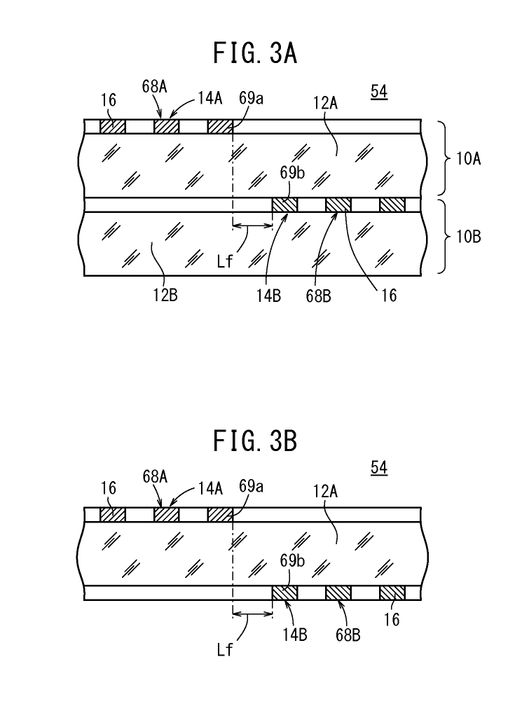

On the other hand, as shown in FIGS. 2, 3A, and 5, the second conductive sheet 10B has a second conductive part 14B formed on one main surface of a second transparent substrate 12B (see FIG. 3A). The second conductive part 14B contains two or more second conductive patterns 64B and third auxiliary patterns 66C (dummy electrodes). The second conductive patterns 64B extend in the second direction (the y direction), are arranged in the first direction (the x direction), each contain a large number of the small lattice 70, and are composed of the thin metal wires 16. The third auxiliary patterns 66C are arranged around the second conductive patterns 64B and are composed of the thin metal wires 16.

The second conductive pattern 64B contains two or more second large lattices 68B. The second large lattices 68B are connected in series in the second direction (the y direction), and each contain a combination of two or more small lattices 70. The above third auxiliary pattern 66C is formed around a side of the second large lattice 68B and is not connected to the second large lattice 68B.

Also the second conductive pattern 64B is not limited to the example using the second large lattices 68B. For example, the second conductive pattern 64B may be formed such that a large number of the small lattices 70 are arranged to form a strip-shaped mesh pattern, and a plurality of the strip-shaped mesh patterns are arranged in parallel and are isolated from each other by insulations. For example, two or more of strip-shaped second conductive patterns 64B may each extend from a terminal in the y direction and may be arranged in the x direction.

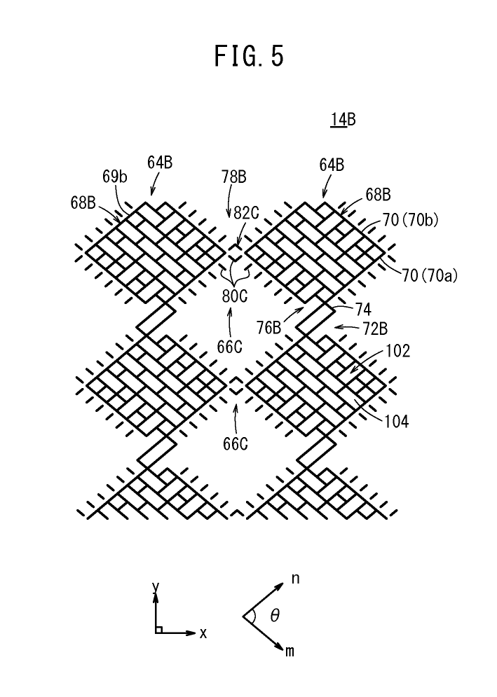

In the case of using the second large lattices 68B in the second conductive patterns 64B, for example, as shown in FIG. 5, second connections 72B composed of the thin metal wires 16 are formed between the second large lattices 68B, and each adjacent two of the second large lattices 68B are electrically connected by the second connection 72B. The second connection 72B contains a medium lattice 74, and the size of the medium lattice 74 corresponds to the total size of p small lattices 70 (in which p is a real number larger than 1) arranged in the fourth direction (the n direction). A second absent portion 76B (a portion provided by removing one side from the small lattice 70) is formed between the medium lattice 74 and a side of the second large lattice 68B extending along the third direction (the m direction).

An electrically isolated second insulation 78B is disposed between the adjacent second conductive patterns 64B.

The third auxiliary pattern 66C contains a plurality of third auxiliary wires 80C (having an axis direction parallel to the fourth direction) arranged along the side of the second large lattice 68B parallel to the third direction, a plurality of third auxiliary wires 80C (having an axis direction parallel to the third direction) arranged along the side of the second large lattice 68B parallel to the fourth direction, and two L-shaped patterns 82C arranged facing each other. Each of the L-shaped patterns 82C is formed by combining two third auxiliary wires 80C into an L shape in the second insulation 78B. The third auxiliary wires 80C and the L-shaped patterns 82C may have a smaller length in the longitudinal direction and thus a dot shape.

In the second large lattices 68B, absent patterns 102 (blank patterns containing no thin metal wires 16) are formed in positions corresponding to the second auxiliary patterns 66B in the first conductive part 14A (see FIG. 4). When the first conductive sheet 10A is stacked on the second conductive sheet 10B, the blank area 100 between the first large lattices 68A overlaps with the second large lattice 68B as hereinafter described. The blank area 100 has the second auxiliary pattern 66B, and the second large lattice 68B has the absent pattern 102 corresponding to the second auxiliary pattern 66B in the position corresponding to the overlap. The absent pattern 102 has an absent portion 104 (provided by removing the thin metal wire 16), and the size of the absent portion 104 corresponds to that of the second auxiliary wire 80B in the second auxiliary pattern 66B. Thus, the absent portion 104 having a size approximately equal to that of the second auxiliary wire 80B is formed in the position corresponding to the overlap of the second auxiliary wire 80B. Of course, in a case where the second auxiliary pattern 66B contains the L-shaped pattern, another absent portion 104 having a size approximately equal to that of the L-shaped pattern is formed in the position corresponding to the overlap of the L-shaped pattern.

The small lattices in the second large lattice 68B include first small lattices 70a having sizes equal to those of the small lattices 70 in the first large lattice 68A and second small lattices 70b having sizes larger than those of the first small lattices 70a. In FIG. 5, the second small lattice 70b has a first shape formed by arranging two first small lattices 70a in the third direction or a second shape formed by arranging two first small lattices 70a in the fourth direction. The second small lattice 70b is not limited to the shapes. The second small lattice 70b has a length component (such as a side), which is s times longer than the side length of the first small lattice 70a (in which s is a real number larger than 1). For example, the length component may be 1.5, 2.5, or 3 times longer than the side length of the first small lattice 70a. As well as the second small lattice 70b, also the second auxiliary wire 80B in the second auxiliary pattern 66B may be s times longer than the side length of the first small lattice 70a (in which s is a real number larger than 1).

As shown in FIG. 2, in the second conductive sheet 10B having the above structure, for example, in each of one end of each alternate (odd-numbered) second conductive pattern 64B and in the other end of each even-numbered second conductive pattern 64B, the second connection 72B is not formed on the open end of the second large lattice 68B. In each of the other end of each odd-numbered second conductive pattern 64B and one end of each even-numbered second conductive pattern 64B, the end of the second large lattice 68B is electrically connected to a second terminal wiring pattern 86b composed of the thin metal wires 16 by a second wire connection 84b.

Thus, as shown in FIG. 2, in the second conductive sheet 10B used in the touch panel 50, a large number of the above second conductive patterns 64B are arranged in the sensing region 60, and a plurality of the second terminal wiring patterns 86b extend from the second wire connections 84b in the terminal wiring region 62.

In the example of FIG. 1, the first conductive sheet 10A and the sensing region 60 each have a rectangular shape as viewed from above. In the terminal wiring region 62, a plurality of first terminals 88a are arranged in the longitudinal center in the length direction of the periphery on one long side of the first conductive sheet 10A. The first wire connections 84a are arranged in a straight line in the y direction along one long side of the sensing region 60 (a long side closest to the one long side of the first conductive sheet 10A). The first terminal wiring pattern 86a extends from each first wire connection 84a to the center of the one long side of the first conductive sheet 10A, and is electrically connected to the corresponding first terminal 88a.

Thus, the first terminal wiring patterns 86a, connected to each pair of corresponding first wire connections 84a formed on the right and left of the one long side of the sensing region 60, have approximately the same lengths. Of course, the first terminals 88a may be formed in a corner of the first conductive sheet 10A or the vicinity thereof. However, in this case, the length difference between the longest first terminal wiring pattern 86a and the shortest first terminal wiring pattern 86a is increased, whereby the longest first terminal wiring pattern 86a and the first terminal wiring patterns 86a in the vicinity thereof are disadvantageously poor in the rate of transferring signal to the corresponding first conductive pattern 64A. Thus, in this embodiment, the first terminals 88a are formed in the longitudinal center of the one long side of the first conductive sheet 10A, whereby the local signal transfer rate deterioration is prevented, resulting in increase of the response speed.

Similarly, as shown in FIG. 1, in the terminal wiring region 62, a plurality of second terminals 88b are arranged in the longitudinal center in the length direction of the periphery on one long side of the second conductive sheet 10B. For example, the odd-numbered second wire connections 84b are arranged in a straight line in the x direction along one short side of the sensing region 60 (a short side closest to one short side of the second conductive sheet 10B), and the even-numbered second wire connections 84b are arranged in a straight line in the x direction along the other short side of the sensing region 60 (a short side closest to the other short side of the second conductive sheet 10B).

For example, each odd-numbered second conductive pattern 64B is connected to the corresponding odd-numbered second wire connection 84b, and each even-numbered second conductive pattern 64B is connected to the corresponding even-numbered second wire connection 84b. The second terminal wiring patterns 86b extend from the odd-numbered and even-numbered second wire connections 84b to the center of one long side of the second conductive sheet 10B, and are each electrically connected to the corresponding second terminal 88b. Thus, for example, the 1st and 2nd second terminal wiring patterns 86b have approximately the same lengths, and similarly the (2n−1)-th and (2n)-th second terminal wiring patterns 86b have approximately the same lengths (n=1, 2, 3, . . . ).

Of course, the second terminals 88b may be formed in a corner of the second conductive sheet 10B or the vicinity thereof. However, in this case, as described above, the longest second terminal wiring pattern 86b and the second terminal wiring patterns 86b in the vicinity thereof are disadvantageously poor in the rate of transferring signal to the corresponding second conductive pattern 64B. Thus, in this embodiment, the second terminals 88b are formed in the longitudinal center of the one long side of the second conductive sheet 10B, whereby the local signal transfer rate deterioration is prevented to increase the response speed.

The first terminal wiring patterns 86a may be arranged in the same manner as the above second terminal wiring patterns 86b, and the second terminal wiring patterns 86b may be arranged in the same manner as the above first terminal wiring patterns 86a.

When the conductive sheet stack 54 is used in the touch panel 50, the protective layer is formed on the first conductive sheet 10A, and the first terminal wiring patterns 86a extending from the first conductive patterns 64A in the first conductive sheet 10A and the second terminal wiring patterns 86b extending from the second conductive patterns 64B in the second conductive sheet 10B are connected to a scan control circuit or the like.

A self or mutual capacitance technology can be preferably used for detecting a touch position. In the self capacitance technology, a voltage signal for the touch position detection is sequentially supplied to the first conductive patterns 64A, and further a voltage signal for the touch position detection is sequentially supplied to the second conductive patterns 64B. When a finger comes into contact with or close to the upper surface of the protective layer 56, the capacitance between the first conductive pattern 64A and the second conductive pattern 64B in the touch position and the GND (ground) is increased, whereby signals from this first conductive pattern 64A and this second conductive pattern 64B have waveforms different from those of signals from the other conductive patterns. Thus, the touch position is calculated by a control circuit based on the signals transmitted from the first conductive pattern 64A and the second conductive pattern 64B. On the other hand, in the mutual capacitance technology, for example, a voltage signal for the touch position detection is sequentially supplied to the first conductive patterns 64A, and the second conductive patterns 64B are sequentially subjected to sensing (transmitted signal detection). When a finger comes into contact with or close to the upper surface of the protective layer 56, the parallel stray capacitance of the finger is added to the parasitic capacitance between the first conductive pattern 64A and the second conductive pattern 64A in the touch position, whereby a signal from this second conductive pattern 64B has a waveform different from those of signals from the other second conductive patterns 64B. Thus, the touch position is calculated by a control circuit based on the order of the first conductive pattern 64A supplied with the voltage signal and the signal transmitted from the second conductive pattern 64B. Even when two fingers come into contact with or close to the upper surface of the protective layer 56 simultaneously, the touch positions can be detected by using the self or mutual capacitance technology. Conventional related detection circuits used in projected capacitive technologies are described in U.S. Pat. Nos. 4,582,955, 4,686,332, 4,733,222, 5,374,787, 5,543,588, and 7,030,860, US Patent Publication No. 2004/0155871, etc.

The side length of each of the first large lattices 68A and the second large lattices 68B is preferably 3 to 10 mm, more preferably 4 to 6 mm. When the side length is less than the lower limit, the first large lattices 68A and the second large lattices 68B are likely to exhibit a lowered electrostatic capacitance to cause a detection trouble. On the other hand, when the side length is more than the upper limit, the position detection accuracy may be deteriorated. For the same reasons, the side length of each small lattice 70 in the first large lattices 68A and the second large lattices 68B is preferably 100 to 400 μm, further preferably 150 to 300 μm, most preferably 210 to 250 μm. When the side length of the small lattice 70 is within this range, the conductive film has high transparency and thereby can be suitably used with excellent visibility on the display panel 58 of the display device 30.

The line width of each of the first auxiliary patterns 66A (the first auxiliary wires 80A), the second auxiliary patterns 66B (the second auxiliary wires 80B), and the third auxiliary patterns 66C (the third auxiliary wires 80C) is 30 μm or less, and may be equal to or different from those of the first conductive patterns 64A and the second conductive patterns 64B. It is preferred that the first conductive patterns 64A, the second conductive patterns 64B, the first auxiliary patterns 66A, the second auxiliary patterns 66B, and the third auxiliary patterns 66C have the same line width.

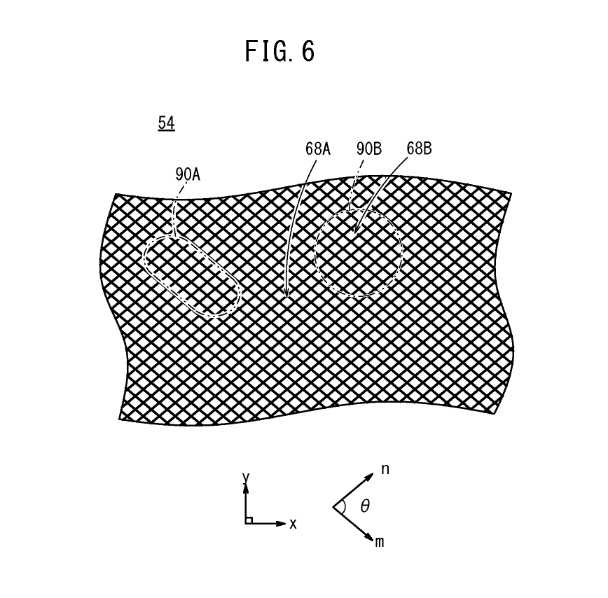

For example, as shown in FIG. 6, when the first conductive sheet 10A is stacked on the second conductive sheet 10B to form the conductive sheet stack 54, the first conductive patterns 64A and the second conductive patterns 64B are crossed. Specifically, the first connections 72A of the first conductive patterns 64A and the second connections 72B of the second conductive patterns 64B are arranged facing each other with the first transparent substrate 12A (see FIG. 3A) interposed therebetween, and also the first insulations 78A of the first conductive part 14A and the second insulations 78B of the second conductive part 14B are arranged facing each other with the first transparent substrate 12A interposed therebetween.

As shown in FIG. 6, when the conductive sheet stack 54 is observed from above, the spaces between the first large lattices 68A of the first conductive sheet 10A are filled with the second large lattices 68B of the second conductive sheet 10B. In this case, the first auxiliary patterns 66A (the dummy electrodes) and the third auxiliary patterns 66C (the dummy electrodes) overlap with each other to form first combined patterns 90A between the first large lattices 68A and the second large lattices 68B, and the second auxiliary patterns 66B (the additional dummy electrodes) in the blank areas 100 between the first large lattices 68A overlap with the absent patterns 102 in the second large lattices 68B to form second combined patterns 90B.

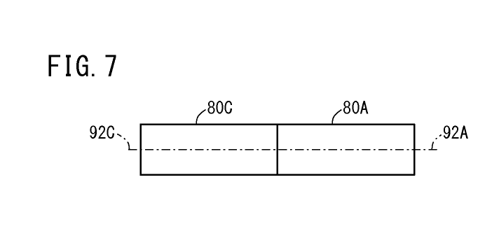

As shown in FIG. 7, in the first combined pattern 90A, an axis 92A of the first auxiliary wire 80A corresponds to an axis 92C of the third auxiliary wire 80C, the first auxiliary wire 80A does not overlap with the third auxiliary wire 80C, and an end of the first auxiliary wire 80A corresponds to an end of the third auxiliary wire 80C, whereby one side of the small lattice 70 is formed. Therefore, the first combined pattern 90A contains a combination of two or more small lattices 70. In the second combined pattern 90B, the absent portion 104 of the absent pattern 102 in the second large lattice 68B is compensated by the second auxiliary wire 80B in the second auxiliary pattern 66B. Therefore, the second combined pattern 90B contains a combination of two or more small lattices 18. Consequently, as shown in FIG. 6, when the conductive sheet stack 54 is observed from above, the entire surface is covered with a large number of the small lattices 70, and the boundaries between the first large lattices 68A and the second large lattices 68B can hardly be found.

For example, in the case of not forming the first auxiliary patterns 66A and the third auxiliary patterns 66C, blank areas corresponding to the widths of the first combined patterns 90A are formed, whereby the edges of the first large lattices 68A and the second large lattices 68B are highly visible, deteriorating the visibility. This problem may be solved by overlapping straight sides 69a of the first large lattices 68A with straight sides 69b of the second large lattices 68B to prevent the formation of the blank areas. However, in a case where the stack position accuracy is slightly deteriorated, the overlaps of the straight sides have large widths (the straight lines are thickened), whereby the boundaries between the first large lattices 68A and the second large lattices 68B are highly visible, deteriorating the visibility.

In contrast, in this embodiment, the first auxiliary wires 80A and the third auxiliary wires 80C are stacked in the above manner, whereby the boundaries between the first large lattices 68A and the second large lattices 68B are made less visible, thereby improving the visibility.

In a case where the straight sides 69a of the first large lattices 68A are overlapped with the straight sides 69b of the second large lattices 68B to prevent the formation of the blank areas as described above, the straight sides 69b of the second large lattices 68B are positioned right under the straight sides 69a of the first large lattices 68A. In this case, all of the straight sides 69a of the first large lattices 68A and the straight sides 69b of the second large lattices 68B function as conductive portions. Therefore, a parasitic capacitance is formed between the straight side 69a of the first large lattice 68A and the straight side 69b of the second large lattice 68B, and the parasitic capacitance acts as a noise on charge information to significantly deteriorate the S/N ratio. Furthermore, since the parasitic capacitance is formed between each pair of the first large lattice 68A and the second large lattice 68B, a large number of the parasitic capacitances are connected in parallel in the first conductive patterns 64A and the second conductive patterns 64B, resulting in increase of the CR time constant. When the CR time constant is increased, there is a possibility that the waveform rise time of the voltage signal supplied to the first conductive pattern 64A (and the second conductive pattern 64B) is increased, and an electric field for the position detection is hardly generated in a predetermined scan time. In addition, there is a possibility that the waveform rise or fall time of the signal transmitted from each of the first conductive patterns 64A and the second conductive patterns 64B is increased, and the waveform change of the transmitted signal cannot be detected in a predetermined scan time. This leads to detection accuracy deterioration and response speed deterioration. Thus, in this case, the detection accuracy and the response speed can be improved only by reducing the number of the first large lattices 68A and the second large lattices 68B (lowering the resolution) or by reducing the size of the display screen, and the conductive sheet stack 54 cannot be used in a large screen such as a B5 sized, A4 sized, or larger screen.

In contrast, in this embodiment, as shown in FIG. 3A, the projected distance Lf between the straight side 69a of the first large lattice 68A and the straight side 69b of the second large lattice 68B is approximately equal to the side length of the small lattice 70. Therefore, only a small parasitic capacitance is formed between the first large lattice 68A and the second large lattice 68B. As a result, the CR time constant can be reduced to improve the detection accuracy and the response speed. In the first combined pattern 90A of the first auxiliary pattern 66A and the third auxiliary pattern 66C, an end of the first auxiliary wire 80A may overlap with an end of the third auxiliary wire 80C. However, this overlap does not result in increase of the parasitic capacitance between the first large lattice 68A and the second large lattice 68B because the first auxiliary wire 80A is unconnected with and electrically isolated from the first large lattice 68A and the third auxiliary wire 80C is unconnected with and electrically isolated from the second large lattice 68B.

It is preferred that the optimum value of the projected distance Lf is appropriately determined depending not on the sizes of the first large lattices 68A and the second large lattices 68B but on the sizes (the line widths and the side lengths) of the small lattices 70 in the first large lattices 68A and the second large lattices 68B. When the small lattices 70 have an excessively large size as compared with the sizes of the first large lattices 68A and the second large lattices 68B, the conductive sheet stack 54 may have a high light transmittance, but the dynamic range of the transmitted signal may be reduced, causing deterioration in the detection sensitivity. On the other hand, when the small lattices 70 have an excessively small size, the conductive sheet stack 54 may have a high detection sensitivity, but the light transmittance may be deteriorated under the restriction of line width reduction.

In a case where the small lattices 70 have a line width of 30 μm or less, the optimum value of the projected distance Lf (the optimum distance) is preferably 100 to 400 μm, more preferably 200 to 300 μm. In a case where the small lattices 70 have a smaller line width, the optimum distance can be further reduced. However, in this case, the electrical resistance may be increased, and the CR time constant may be increased even under a small parasitic capacitance, resulting in deterioration in the detection sensitivity and the response speed. Thus, the line width of the small lattice 70 is preferably within the above range.

For example, the sizes of the first large lattices 68A, the second large lattices 68B, and the small lattices 70 are determined based on the size of the display panel 58 or the size and touch position detection resolution (drive pulse period or the like) of the sensing region 60, and the optimum distance between the first large lattice 68A and the second large lattice 68B is obtained based on the line width of the small lattice 70.

In a case where the absent patterns 102 are not formed in the second large lattice 68B, the light transmittance difference between a portion corresponding to the first large lattice 68A and a portion corresponding to the second large lattice 68B is increased in the conductive sheet stack 54, deteriorating the visibility (making the first large lattice 68A or the second large lattice 68B highly visible). Thus, in this embodiment, the absent patterns 102 are formed in the second large lattice 68B, whereby the portions corresponding to the first large lattice 68A and the second large lattice 68B have uniform light transmittance to improve the visibility. In view of achieving the uniform light transmittance, the difference between the light shielding ratio of the first large lattices 68A and the light shielding ratio of the overlaps of the second large lattices 68B and the second auxiliary patterns 66B is preferably 20% or less, further preferably 10% or less.

The light shielding ratio of the first large lattices 68A is a value (%) calculated by [(Ia1−Ib1)/Ia1]×100, in which Ia1 represents an intensity of light introduced to the first large lattices 68A and Ib1 represents an intensity of light transmitted through the first large lattices 68A. Similarly, the light shielding ratio of the overlaps of the second large lattices 68B and the second auxiliary patterns 66B is a value (%) calculated by [(Ia2−Ib2)/Ia2]×100, in which Ia2 represents an intensity of light introduced to the overlaps and Ib2 represents an intensity of light transmitted through the overlaps.

Though, in the absent pattern 102 of the second large lattice 68B, the absent portion 104 having a size approximately equal to that of the second auxiliary wire 80B is formed in the position corresponding to the second auxiliary wire 80B in the above example, the absent portion 104 is not limited to this example. The absent portion 104 may be formed in a position different from the position corresponding to the overlap of the second auxiliary wire 80B, as long as the portions corresponding to the first large lattice 68A and the second large lattice 68B have uniform light transmittance.

In a case where the number of the second auxiliary wires 80B is increased in the second auxiliary pattern 66B, it is necessary to increase the number of the absent portions 104 in the second large lattice 68B in view of achieving the above uniform light transmittance. In this case, there is a possibility that the conductivity of the second large lattice 68B is deteriorated. Accordingly, the light shielding ratio of the second auxiliary patterns 66B is preferably 50% or less, further preferably 25% or less, of the light shielding ratio of the first large lattices 68A.

The light shielding ratio of the second auxiliary patterns 66B is a value (%) calculated by [(Ia3−Ib3)/Ia3]×100, in which Ia3 represents an intensity of light introduced to the blank areas 100 between the first large lattices 68A and Ib3 represents an intensity of light transmitted through the second auxiliary patterns 66B.

In this embodiment, the first large lattice 68A contains only the first small lattices 70a, and the second large lattice 68B contains the combination of the first small lattices 70a and the second small lattices 70b. Therefore, the occupation area of the thin metal wires 16 in the first large lattices 68A is larger than that in the second large lattices 68B. Thus, for example, in the case of using a mutual capacitance technology for the finger touch position detection, the first large lattices 68A having the larger occupation area can be used as drive electrodes, the second large lattices 68B can be used as receiving electrodes, and the receiving sensitivity of the second large lattices 68B can be improved.

In this embodiment, the occupation area of the thin metal wires 16 in the first conductive patterns 64A is larger than that in the second conductive patterns 64B. Therefore, the first conductive patterns 64A can have a low surface resistance of 70 ohm/sq or less. Consequently, the conductive sheet stack 54 is advantageous in reducing noise impact of an electromagnetic wave from the display device 30 or the like.

When the thin metal wires 16 in the first conductive patterns 64A have an occupation area A1 and the thin metal wires 16 in the second conductive patterns 64B have an occupation area A2, the conductive sheet stack 54 preferably satisfies the condition of 1<A1/A2≦20, further preferably satisfies the condition of 1<A1/A2≦10, and particularly preferably satisfies the condition of 2≦A1/A2≦10.

When the thin metal wires 16 in the first large lattices 68A have an occupation area a1 and the thin metal wires 16 in the second large lattices 68B have an occupation area a2, the conductive sheet stack 12 preferably satisfies the condition of 1<a1/a2≦20, further preferably satisfies the condition of 1<a1/a2≦10, and particularly preferably satisfies the condition of 2≦a1/a2≦10.

In this embodiment, in the terminal wiring region 62, the first terminals 88a are formed in the longitudinal center of the periphery on the one long side of the first conductive sheet 10A, and the second terminals 88b are formed in the longitudinal center of the periphery on the one long side of the second conductive sheet 10B. Particularly, in the example of FIG. 1, the first terminals 88a and the second terminals 88b are close to each other and do not overlap with each other, and the first terminal wiring patterns 86a and the second terminal wiring patterns 86b do not overlap with each other. For example, the first terminal 88a may partially overlap with the odd-numbered second terminal wiring pattern 86b.

Thus, the first terminals 88a and the second terminals 88b can be electrically connected to the control circuit by using a cable and two connectors (a connector for the first terminals 88a and a connector for the second terminals 88b) or one connector (a complex connector for the first terminals 88a and the second terminals 88b).

Since the first terminal wiring patterns 86a and the second terminal wiring patterns 86b do not vertically overlap with each other, the generation of the parasitic capacitance between the first terminal wiring patterns 86a and the second terminal wiring patterns 86b is reduced to prevent the response speed deterioration.

Since the first wire connections 84a are arranged along the one long side of the sensing region 60 and the second wire connections 84b are arranged along the both short sides of the sensing region 60, the area of the terminal wiring region 62 can be reduced. Therefore, the size of the display panel 58 containing the touch panel 50 can be easily reduced, and the display screen 58a can be made to seem larger. Also the operability of the touch panel 50 can be improved.

The area of the terminal wiring region 62 may be further reduced by reducing the distance between the adjacent first terminal wiring patterns 86a or the adjacent second terminal wiring patterns 86b. The distance is preferably 10 μm or more and 50 μm or less in view of preventing migration.

Alternatively, the area of the terminal wiring region 62 may be reduced by arranging the second terminal wiring pattern 86b between the adjacent first terminal wiring patterns 86a in the view from above. However, when the pattern is misaligned, the first terminal wiring pattern 86a may vertically overlap with the second terminal wiring pattern 86b, increasing the parasitic capacitance therebetween undesirably. This leads to deterioration of the response speed. Thus, in the case of using such an arrangement, the distance between the adjacent first terminal wiring patterns 86a is preferably 50 μm or more and 100 μm or less.

As shown in FIG. 1, first alignment marks 94a and second alignment marks 94b are preferably formed on the corners etc. of the first conductive sheet 10A and the second conductive sheet 10B. The first alignment marks 94a and the second alignment marks 94b are used for positioning the sheets in the process of bonding the sheets. When the first conductive sheet 10A and the second conductive sheet 10B are bonded to obtain the conductive sheet stack 54, the first alignment marks 94a and the second alignment marks 94b form composite alignment marks. The composite alignment marks may be used for positioning the conductive sheet stack 54 in the process of attaching the conductive sheet stack 54 to the display panel 58.

In the conductive sheet stack 54, the CR time constant of a large number of the first conductive patterns 64A and the second conductive patterns 64B can be significantly reduced, whereby the response speed can be increased, and the position detection can be readily carried out in an operation time (a scan time). Thus, the screen sizes (not the thickness but the length and width) of the touch panel 50 can be easily increased.

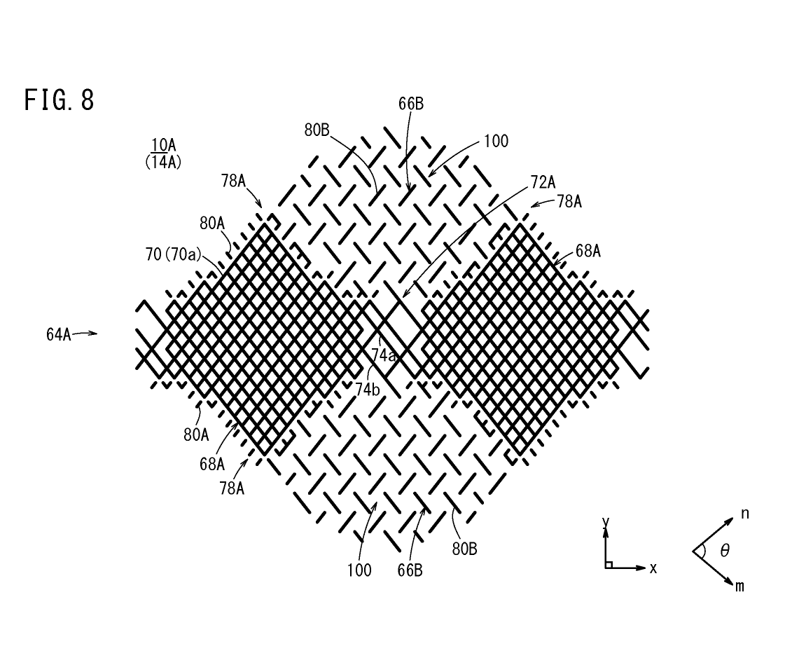

Several variant examples of the first conductive patterns 64A and the second conductive patterns 64B will be described below with reference to FIGS. 8 to 12.

As shown in FIG. 8, a first conductive pattern 64A according to a first variant example contains two or more first large lattices 68A. The first large lattices 68A are connected in series in the first direction (the x direction), and each contain a combination of two or more small lattices 70. A first auxiliary pattern 66A is formed around a side of the first large lattice 68A, and is not connected to the first large lattice 68A.

First connections 72A composed of the thin metal wires 16 are formed between the first large lattices 68A, and each adjacent two of the first large lattices 68A are electrically connected by the first connection 72A. The first connection 72A contains a first medium lattice 74a and a second medium lattice 74b. The size of the first medium lattice 74a corresponds to the total size of p small lattices 70 (in which p is a real number larger than 1) arranged in the third direction (the m direction). The size of the second medium lattice 74b corresponds to the total size of q small lattices 70 (in which q is a real number larger than 1) arranged in the third direction (the m direction), and r small lattices 70 (in which r is a real number larger than 1) arranged in the fourth direction (the n direction). The second medium lattice 74b is crossed with the first medium lattice 74a. In the example of FIG. 8, the size of the first medium lattice 74a corresponds to the total size of seven small lattices 70 arranged in the third direction, and the second medium lattice 74b is such sized that three small lattices 70 are arranged in the third direction and five small lattices 70 are arranged in the fourth direction. The angle θ between the third and fourth directions may be appropriately selected within a range of 60° to 120°. Furthermore, in the first conductive pattern 64A, second auxiliary patterns 66B composed of the thin metal wires 16 are formed in blank areas 100 (light-transmitting areas) between the first large lattices 68A.

The first auxiliary patterns 66A contain a plurality of first auxiliary wires 80A, L-shaped patterns, and U- and E-shaped patterns provided by combining the first auxiliary wire 80A and the thin metal wire corresponding to one side of the small lattice 70.

In the second auxiliary pattern 66B formed in the blank area 100 between the first large lattices 68A, second auxiliary wires 80B having an axis direction parallel to the third direction (the m direction) and second auxiliary wires 80B having an axis direction parallel to the fourth direction (the n direction) are alternately arranged, and the second auxiliary wires 80B are electrically isolated from each other (e.g. arranged at a distance corresponding to the side length of the small lattice 70).

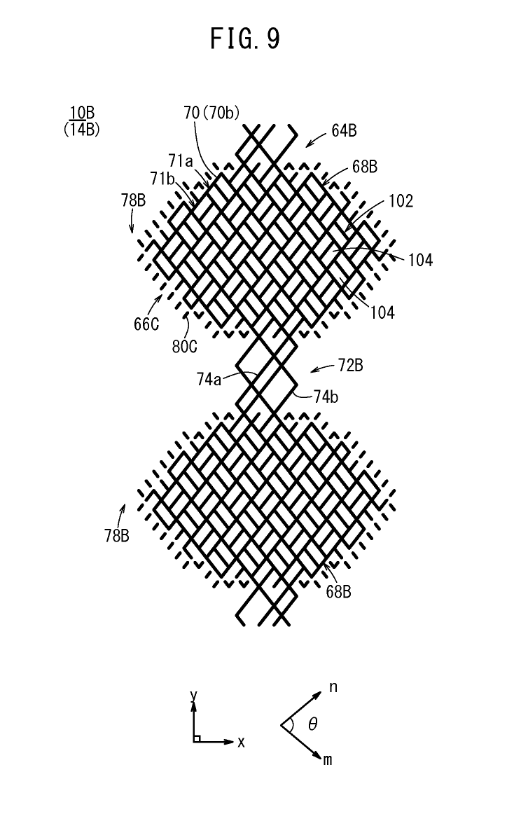

As shown in FIG. 9, a second conductive pattern 64B according to the first variant example contains two or more second large lattices 68B. The second large lattices 68B are connected in series in the second direction (the y direction). A third auxiliary pattern 66C is formed around a side of the second large lattice 68B, and is not connected to the second large lattice 68B. Second connections 72B composed of the thin metal wires 16 are formed between the second large lattices 68B, and each adjacent two of the second large lattices 68B are electrically connected by the second connection 72B.

The second connection 72B contains a first medium lattice 74a and a second medium lattice 74b. The size of the first medium lattice 74a corresponds to the total size of p small lattices 70 (p first small lattices 70a, in which p is a real number larger than 1) arranged in the fourth direction (the n direction). The size of the second medium lattice 74b corresponds to the total size of q small lattices 70 (in which q is a real number larger than 1) arranged in the fourth direction (the n direction), and r small lattices 70 (in which r is a real number larger than 1) arranged in the third direction (the m direction). The second medium lattice 74b is crossed with the first medium lattice 74a. In the example of FIG. 9, the size of the first medium lattice 74a corresponds to the total size of seven small lattices 70 arranged in the fourth direction, and the second medium lattice 74b is arranged such that three small lattices 70 are arranged in the fourth direction and five small lattices 70 are arranged in the third direction.

The third auxiliary pattern 66C contains a plurality of third auxiliary wires 80C, L-shaped patterns, etc.

In the second large lattices 68B, absent patterns 102 (blank patterns containing no thin metal wires 16) are formed in positions corresponding to the second auxiliary patterns 66B adjacent to the first conductive patterns 64A (see FIG. 8). The absent pattern 102 has an absent portion 104 corresponding to the second auxiliary wire 80B in the second auxiliary pattern 66B (provided by removing the thin metal wire 16). Thus, the absent portion 104 having a size approximately equal to that of the second auxiliary wire 80B is formed in the position corresponding to the overlap of the second auxiliary wire 80B.

The second large lattice 68B is mainly composed of a plurality of second small lattices 70b larger than first small lattices 70a. In FIG. 9, the second small lattice 70b has a first shape formed by arranging two first small lattices 70a in the third direction or a second shape formed by arranging two first small lattices 70a in the fourth direction. The second small lattice 70b is not limited to the shapes. The second small lattice 70b has a length component (such as a side), which is s times longer than the side length of the first small lattice 70a (in which s is a real number larger than 1). For example, the length component may be 1.5, 2.5, or 3 times longer than the side length of the first small lattice 70a. As well as the second small lattices 70b, also the second auxiliary wire 80B in the second auxiliary pattern 66B may be s times longer than the side length of the first small lattice 70a (in which s is a real number larger than 1).

In the second large lattice 68B, first combined shapes 71a, which each contain a combination of two first shapes arranged in the third direction, and second combined shapes 71b, which each contain a combination of two second shapes arranged in the fourth direction, are alternately arranged. When the first conductive sheet 10A is stacked on the second conductive sheet 10B, the thin metal wire between the adjacent first shapes (extending in the third direction) intersects with the second auxiliary wire 80B extending in the fourth direction, and the thin metal wire between the adjacent second shapes (extending in the fourth direction) intersects with the second auxiliary wire 80B extending in the third direction.

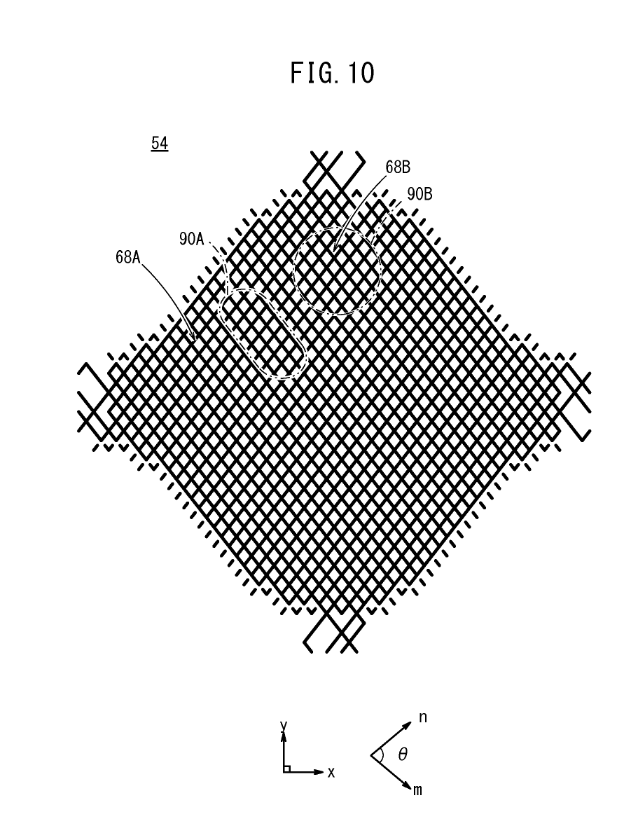

Therefore, as shown in FIG. 10, the first auxiliary patterns 66A and the third auxiliary patterns 66C overlap with each other to form first combined patterns 90A, and each first combined pattern 90A contains a combination of two or more small lattices 70.

Furthermore, the second auxiliary patterns 66B formed in the blank areas 100 between the first large lattices 68A overlap with the absent patterns 102 in the second large lattices 68B to form second combined patterns 90B. In the second combined pattern 90B, the absent portion 104 of the absent pattern 102 in the second large lattice 68B is compensated by the second auxiliary wire 80B in the second auxiliary pattern 66B. Therefore, the second combined pattern 90B contains a combination of two or more small lattices 70. Consequently, as shown in FIG. 10, when the conductive sheet stack 54 is observed from above, the entire surface is covered with a large number of the small lattices 70, and the boundaries between the first large lattices 68A and the second large lattices 68B can hardly be found.

A first conductive pattern 64A and a second conductive pattern 64B according to a second variant example have approximately the same structures as those of the first variant example, but are different in the patterns of the second large lattices 68B and the second auxiliary patterns 66B in the blank areas 100 between the first large lattices 68A, as described below.

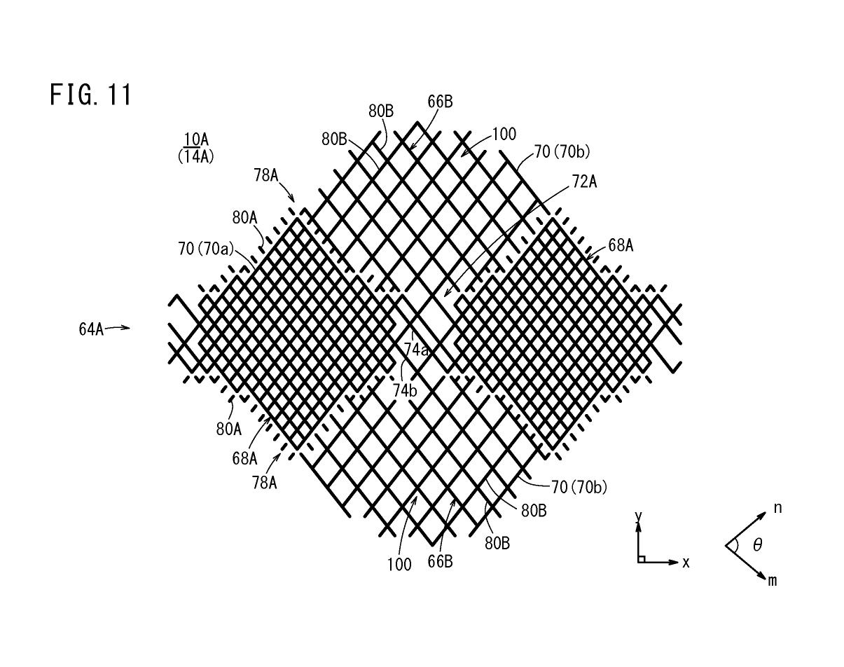

As shown in FIG. 11, in the second auxiliary pattern 66B, a plurality of second auxiliary wires 80B, which have an axis direction parallel to the third direction (the m direction) and are arranged in the fourth direction, intersect with a plurality of second auxiliary wires 80B, which have an axis direction parallel to the fourth direction (the n direction) and are arranged in the third direction. Thus, the second auxiliary pattern 66B contains a combination of a plurality of second small lattices 70b, and the second small lattice 70b is sized such that two first small lattices 70a are arranged in the third direction and two first small lattices 70a are arranged in the fourth direction.

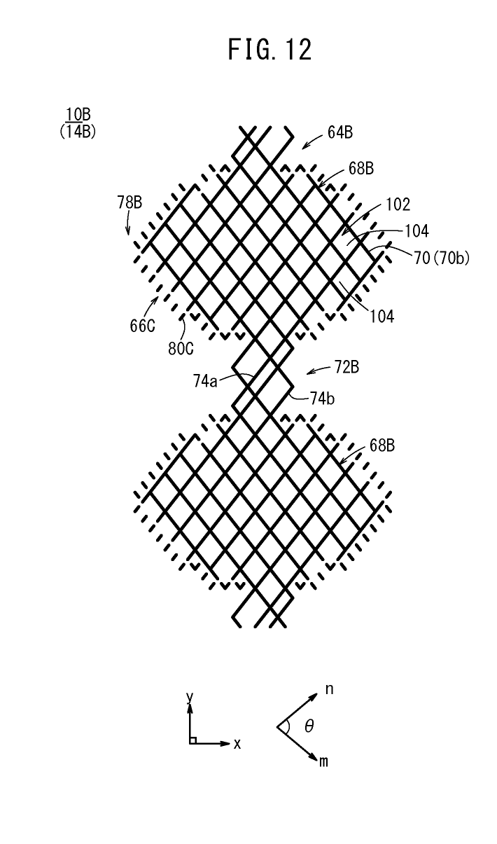

As shown in FIG. 12, absent patterns 102 corresponding to the second auxiliary patterns 66B (see FIG. 11) are formed in the second large lattices 68B. The absent pattern 102 has an absent portion 104 in a position facing an intersection of the second auxiliary wires 80B in the second auxiliary pattern 66B, and the absent portion 104 has a size approximately equal to that of the second small lattice 70b. Thus, the second large lattice 68B contains a combination of the second small lattices 70b, and the size of the second small lattice 70b in the second large lattice 68B is equal to that of the second small lattice 70b in the second auxiliary pattern 66B. The position relation between the second large lattice 68B and the second auxiliary pattern 66B is such that the second small lattices 70b in the second large lattice 68B are displaced in each of the third and fourth directions by a distance corresponding to the side length of the first small lattice 70a from the second small lattices 70b in the second auxiliary pattern 66B.

Therefore, also in the second variant example, as shown in FIG. 10, the first auxiliary patterns 66A and the third auxiliary patterns 66C overlap with each other to form the first combined patterns 90A, and each first combined pattern 90A contains a combination of two or more small lattices 70.

Furthermore, the second auxiliary patterns 66B formed in the blank areas 100 between the first large lattices 68A overlap with the absent patterns 102 in the second large lattices 68B to form second combined patterns 90B. In the second combined pattern 90B, the absent portion 104 of the absent pattern 102 in the second large lattice 68B is compensated by the second auxiliary wire 80B in the second auxiliary pattern 66B. Therefore, the second combined pattern 90B contains a combination of two or more small lattices 70. Consequently, as shown in FIG. 10, when the conductive sheet stack 54 is observed from above, the entire surface is covered with a large number of the small lattices 70, and the boundaries between the first large lattices 68A and the second large lattices 68B can hardly be found.

Though the first conductive sheet 10A and the second conductive sheet 10B are used in the projected capacitive touch panel 50 in the above embodiment, they may be used in a surface capacitive touch panel or a resistive touch panel.

In the above conductive sheet stack 54, as shown in FIGS. 2 and 3A, the first conductive part 14A is formed on the one main surface of the first transparent substrate 12A, the second conductive part 14B is formed on the one main surface of the second transparent substrate 12B, and they are stacked. Alternatively, as shown in FIG. 3B, the first conductive part 14A may be formed on the one main surface of the first transparent substrate 12A, and the second conductive part 14B may be formed on the other main surface of the first transparent substrate 12A. In this case, the second transparent substrate 12B is not used, the first transparent substrate 12A is stacked on the second conductive part 14B, and the first conductive part 14A is stacked on the first transparent substrate 12A. In addition, another layer may be disposed between the first conductive sheet 10A and the second conductive sheet 10B. The first conductive part 14A and the second conductive part 14B may be arranged facing each other as long as they are insulated.

The first conductive patterns 64A and the second conductive patterns 64B may be formed as follows. For example, a photosensitive material having the first transparent substrate 12A or the second transparent substrate 12B and thereon a photosensitive silver halide-containing emulsion layer may be exposed and developed, whereby metallic silver portions and light-transmitting portions may be formed in the exposed areas and the unexposed areas respectively to obtain the first conductive patterns 64A and the second conductive patterns 64B. The metallic silver portions may be subjected to a physical development treatment and/or a plating treatment to deposit a conductive metal on the metallic silver portions.

As shown in FIG. 3B, the first conductive part 14A may be formed on the one main surface of the first transparent substrate 12A, and the second conductive part 14B may be formed on the other main surface thereof. In this case, if the one main surface is exposed and then the other main surface is exposed in the usual method, the desired patterns cannot be obtained on the first conductive part 14A and the second conductive part 14B occasionally. In particular, it is difficult to uniformly form the patterns of a large number of the first auxiliary wires 80A arranged along the straight sides 69a of the first large lattices 68A, the L-shaped patterns 82A in the first insulations 78A, the patterns of a large number of the third auxiliary wires 80C arranged along the straight sides 69b of the second large lattices 68B, the L-shaped patterns 82C in the second insulations 78B, and the like.

Therefore, the following production method can be preferably used.

Thus, the first conductive patterns 64A on the one main surface and the second conductive patterns 64B on the other main surface are formed by subjecting the photosensitive silver halide emulsion layers on both sides of the first transparent substrate 12A to one-shot exposure.

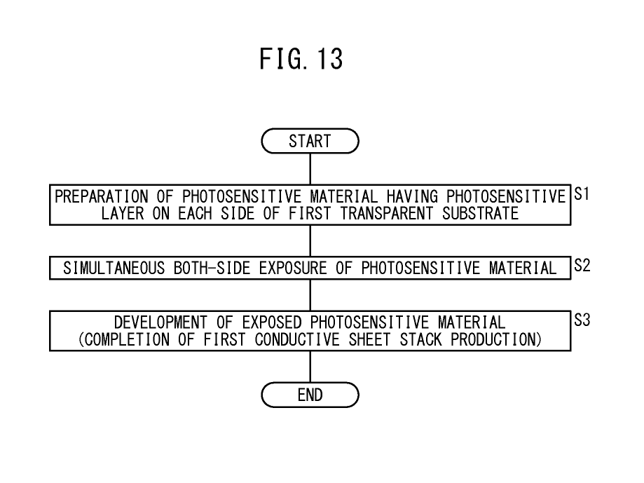

A specific example of the production method will be described below with reference to FIGS. 13 to 15.

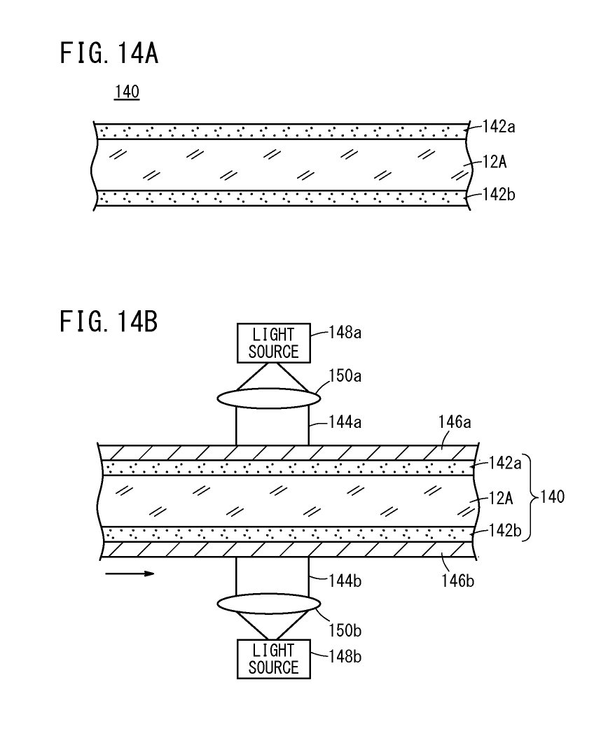

First, in step S1 of FIG. 13, a long photosensitive material 140 is prepared. As shown in FIG. 14A, the photosensitive material 140 has the first transparent substrate 12A, a photosensitive silver halide emulsion layer formed on one main surface of the first transparent substrate 12A (hereinafter referred to as the first photosensitive layer 142a), and a photosensitive silver halide emulsion layer formed on the other main surface of the first transparent substrate 12A (hereinafter referred to as the second photosensitive layer 142b).

In step S2 of FIG. 13, the photosensitive material 140 is exposed. In this exposure step, a simultaneous both-side exposure, which includes a first exposure treatment for irradiating the first photosensitive layer 142a on the first transparent substrate 12A with a light in a first exposure pattern and a second exposure treatment for irradiating the second photosensitive layer 142b on the first transparent substrate 12A with a light in a second exposure pattern, is carried out. In the example of FIG. 14B, the first photosensitive layer 142a is irradiated through a first photomask 146a with a first light 144a (a parallel light), and the second photosensitive layer 142b is irradiated through a second photomask 146b with a second light 144b (a parallel light), while conveying the long the photosensitive material 140 in one direction. The first light 144a is obtained such that a light from a first light source 148a is converted to the parallel light by an intermediate first collimator lens 150a, and the second light 144b is obtained such that a light from a second light source 148b is converted to the parallel light by an intermediate second collimator lens 150b. Though two light sources (the first light source 148a and the second light source 148b) are used in the example of FIG. 14B, only one light source may be used. In this case, a light from the one light source may be divided by an optical system into the first light 144a and the second light 144b for exposing the first photosensitive layer 142a and the second photosensitive layer 142b.

In the step S3 of FIG. 13, the exposed the photosensitive material 140 is developed to prepare e.g. the conductive sheet stack 54 shown in FIG. 3B. The conductive sheet stack 54 has the first transparent substrate 12A, the first conductive part 14A (including the first conductive patterns 64A) formed in the first exposure pattern on the one main surface of the first transparent substrate 12A, and the second conductive part 14B (including the second conductive patterns 64B) formed in the second exposure pattern on the other main surface of the first transparent substrate 12A. Preferred exposure time and development time for the first photosensitive layer 142a and the second photosensitive layer 142b depend on the types of the first light source 148a, the second light source 148b, and a developer, etc., and cannot be categorically determined. The exposure time and development time may be selected in view of achieving a development ratio of 100%.

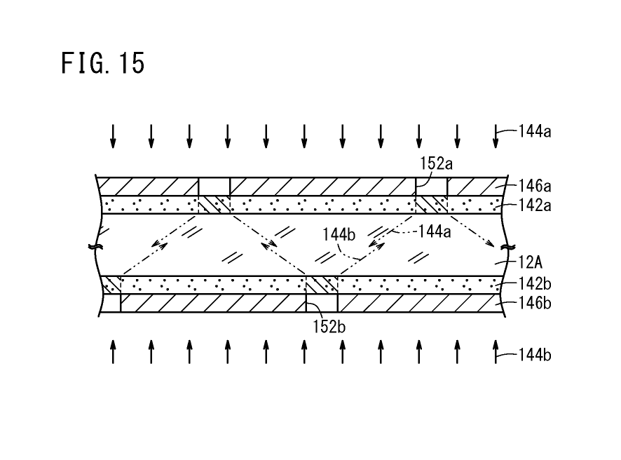

As shown in FIG. 15, in the first exposure treatment in the production method of this embodiment, for example, the first photomask 146a is placed on the first photosensitive layer 142a in close contact therewith, the first light source 148a is arranged facing the first photomask 146a, and the first light 144a is emitted from the first light source 148a toward the first photomask 146a, so that the first photosensitive layer 142a is exposed. The first photomask 146a has a glass substrate composed of a transparent soda glass and a mask pattern (a first exposure pattern 152a) formed thereon. Therefore, in the first exposure treatment, areas in the first photosensitive layer 142a, corresponding to the first exposure pattern 152a in the first photomask 146a, are exposed. A space of approximately 2 to 10 μm may be formed between the first photosensitive layer 142a and the first photomask 146a.

Similarly, in the second exposure treatment, for example, the second photomask 146b is placed on the second photosensitive layer 142b in close contact therewith, the second light source 148b is arranged facing the second photomask 146b, and the second light 144b is emitted from the second light source 148b toward the second photomask 146b, so that the second photosensitive layer 142b is exposed. The second photomask 146b, as well as the first photomask 146a, has a glass substrate composed of a transparent soda glass and a mask pattern (a second exposure pattern 152b) formed thereon. Therefore, in the second exposure treatment, areas in the second photosensitive layer 142b, corresponding to the second exposure pattern 152b in the second photomask 146b, are exposed. In this case, a space of approximately 2 to 10 μm may be formed between the second photosensitive layer 142b and the second photomask 146b.

In the first and second exposure treatments, the emission of the first light 144a from the first light source 148a and the emission of the second light 144b from the second light source 148b may be carried out simultaneously or independently. If the emissions are simultaneously carried out, the first photosensitive layer 142a and the second photosensitive layer 142b can be simultaneously exposed in one exposure process to reduce the treatment time.

In a case where both of the first photosensitive layer 142a and the second photosensitive layer 142b are not spectrally sensitized, a light incident on one side may affect the image formation on the other side (the back side) in the both-side exposure of the photosensitive material 140.

Thus, the first light 144a from the first light source 148a reaches the first photosensitive layer 142a and is scattered by silver halide particles in the first photosensitive layer 142a, and a part of the scattered light is transmitted through the first transparent substrate 12A and reaches the second photosensitive layer 142b. Then, a large area of the boundary between the second photosensitive layer 142b and the first transparent substrate 12A is exposed to form a latent image. As a result, the second photosensitive layer 142b is exposed to the second light 144b from the second light source 148b and the first light 144a from the first light source 148a. When the second photosensitive layer 142b is developed to prepare the conductive sheet stack 54, the conductive pattern corresponding to the second exposure pattern 152b (the second conductive part 14B) is formed, and additionally a thin conductive layer is formed due to the first light 144a from the first light source 148a between the conductive patterns, so that the desired pattern (corresponding to the second exposure pattern 152b) cannot be obtained. This is true also for the first photosensitive layer 142a.

As a result of intense research in view of solving this problem, it has been found that when the thicknesses and the applied silver amounts of the first photosensitive layer 142a and the second photosensitive layer 142b are selected within particular ranges, the incident light can be absorbed by the silver halide to suppress the light transmission to the back side. In this embodiment, the thicknesses of the first photosensitive layer 142a and the second photosensitive layer 142b may be 1 to 4 μm. The upper limit is preferably 2.5 μm. The applied silver amounts of the first photosensitive layer 142a and the second photosensitive layer 142b may be 5 to 20 g/m².

In the above described exposure technology in close-contact with both sides, the exposure may be inhibited by dust or the like attached to the film surface to generate an image defect. It is known that the dust attachment can be prevented by applying a conductive substance such as a metal oxide or a conductive polymer to the film. However, the metal oxide or the like remains in the processed product to deteriorate the transparency of the final product, and the conductive polymer is disadvantageous in storage stability, etc. As a result of intense research, it has been found that a silver halide layer with reduced binder content exhibits a satisfactory conductivity for static charge prevention. Thus, the volume ratio of silver/binder is controlled in the first photosensitive layer 142a and the second photosensitive layer 142b. The silver/binder volume ratios of the first photosensitive layer 142a and the second photosensitive layer 142b are 1/1 or more, preferably 2/1 or more.

In a case where the thicknesses, the applied silver amounts, and the silver/binder volume ratios of the first photosensitive layer 142a and the second photosensitive layer 142b are selected as described above, the first light 144a emitted from the first light source 148a to the first photosensitive layer 142a does not reach the second photosensitive layer 142b as shown in FIG. 15. Similarly, the second light 144b emitted from the second light source 148b to the second photosensitive layer 142b does not reach the first photosensitive layer 142a. As a result, in the following development for producing the conductive sheet stack 54, as shown in FIG. 3B, only the conductive pattern corresponding to the first exposure pattern 152a (the pattern of the first conductive part 14A) is formed on the one main surface of the first transparent substrate 12A, and only the conductive pattern corresponding to the second exposure pattern 152b (the pattern of the second conductive part 14B) is formed on the other main surface of the first transparent substrate 12A, so that the desired patterns can be obtained.

In the production method using the above one-shot exposure on both sides, the first photosensitive layer 142a and the second photosensitive layer 142b can have both of the satisfactory conductivity and both-side exposure suitability, and the same or different patterns can be formed on the surfaces of the one first transparent substrate 12A by the exposure, whereby the electrodes of the touch panel 50 can be easily formed, and the touch panel 50 can be made thinner (smaller).

In the above production method, the first conductive patterns 64A and the second conductive patterns 64B are formed using the photosensitive silver halide emulsion layers. The other production methods include the following methods.

A photosensitive plating base layer containing a pre-plating treatment material may be formed on the first transparent substrate 12A or the second transparent substrate 12B. The resultant layer may be exposed and developed, and may be subjected to a plating treatment, whereby metal portions and light-transmitting portions may be formed in the exposed areas and the unexposed areas respectively to form the first conductive patterns 64A or the second conductive patterns 64B. The metal portions may be further subjected to a physical development treatment and/or a plating treatment to deposit a conductive metal thereon.

The following two processes can be preferably used in the method using the pre-plating treatment material. The processes are disclosed more specifically in Japanese Laid-Open Patent Publication Nos. 2003-213437, 2006-064923, 2006-058797, and 2006-135271, etc.

(a) A process comprising applying, to a transparent substrate, a plating base layer having a functional group interactable with a plating catalyst or a precursor thereof, exposing and developing the layer, and subjecting the developed layer to a plating treatment to form a metal portion on the plating base material.

(b) A process comprising applying, to a transparent substrate, an underlayer containing a polymer and a metal oxide and a plating base layer having a functional group interactable with a plating catalyst or a precursor thereof in this order, exposing and developing the layers, and subjecting the developed layers to a plating treatment to form a metal portion on the plating base material.

Alternatively, a photoresist film on a copper foil disposed on the first transparent substrate 12A or the second transparent substrate 12B may be exposed and developed to form a resist pattern, and the copper foil exposed from the resist pattern may be etched to form the first conductive part 14A or the second conductive part 14B.

A paste containing fine metal particles may be printed on the first transparent substrate 12A or the second transparent substrate 12B, and the printed paste may be plated with a metal to form the first conductive part 14A or the second conductive part 14B.

The first conductive part 14A or the second conductive part 14B may be printed on the first transparent substrate 12A or the second transparent substrate 12B by using a screen or gravure printing plate.

The first conductive patterns 64A or the second conductive patterns 64B may be formed on the first transparent substrate 12A or the second transparent substrate 12B by using an inkjet method.

A particularly preferred method, which contains using a photographic photosensitive silver halide material for producing the first conductive sheet 10A or the second conductive sheet 10B of this embodiment, will be mainly described below.

The method for producing the first conductive sheet 10A or the second conductive sheet 10B of this embodiment includes the following three processes different in the photosensitive materials and development treatments.

(1) A process comprising subjecting a photosensitive black-and-white silver halide material free of physical development nuclei to a chemical or thermal development to form the metallic silver portions on the photosensitive material.

(2) A process comprising subjecting a photosensitive black-and-white silver halide material having a silver halide emulsion layer containing physical development nuclei to a physical solution development to form the metallic silver portions on the photosensitive material.

(3) A process comprising subjecting a stack of a photosensitive black-and-white silver halide material free of physical development nuclei and an image-receiving sheet having a non-photosensitive layer containing physical development nuclei to a diffusion transfer development to form the metallic silver portions on the non-photosensitive image-receiving sheet.

In the process of (1), an integral black-and-white development procedure is used to form a transmittable conductive film such as a light-transmitting conductive film on the photosensitive material. The resulting silver is a chemically or thermally developed silver in the state of a high-specific surface area filament, and thereby shows a high activity in the following plating or physical development treatment.

In the process of (2), the silver halide particles are melted around and deposited on the physical development nuclei in the exposed areas to form a transmittable conductive film such as a light-transmitting conductive film on the photosensitive material. Also in this process, an integral black-and-white development procedure is used. Though high activity can be achieved since the silver halide is deposited on the physical development nuclei in the development, the developed silver has a spherical shape with small specific surface.

In the process of (3), the silver halide particles are melted in the unexposed areas, and are diffused and deposited on the development nuclei of the image-receiving sheet, to form a transmittable conductive film such as a light-transmitting conductive film on the sheet. In this process, a so-called separate-type procedure is used, the image-receiving sheet being peeled off from the photosensitive material.

A negative or reversal development treatment can be used in the processes. In the diffusion transfer development, the negative development treatment can be carried out using an auto-positive photosensitive material.

The chemical development, thermal development, physical solution development, and diffusion transfer development have the meanings generally known in the art, and are explained in common photographic chemistry texts such as Shin-ichi Kikuchi, “Shashin Kagaku (Photographic Chemistry)”, Kyoritsu Shuppan Co., Ltd., 1955 and C. E. K. Mees, “The Theory of Photographic Processes, 4th ed.”, Mcmillan, 1977. A liquid treatment is generally used in the present invention, and also a thermal development treatment can be utilized. For example, techniques described in Japanese Laid-Open Patent Publication Nos. 2004-184693, 2004-334077, and 2005-010752 and Japanese Patent Application Nos. 2004-244080 and 2004-085655 can be used in the present invention.

The structure of each layer in the first conductive sheet 10A and the second conductive sheet 10B of this embodiment will be described in detail below.

### [First Transparent Substrate 12A and Second Transparent Substrate 12B]

The first transparent substrate 12A and the second transparent substrate 12B may be a plastic film, a plastic plate, a glass plate, etc.

Examples of materials for the plastic film and the plastic plate include polyesters such as polyethylene terephthalates (PET) and polyethylene naphthalates (PEN); polyolefins such as polyethylenes (PE), polypropylenes (PP), polystyrenes, and EVA; vinyl resins; polycarbonates (PC); polyamides; polyimides; acrylic resins; and triacetyl celluloses (TAC).

The first transparent substrate 12A and the second transparent substrate 12B are preferably a film or plate of a plastic having a melting point of about 290° C. or lower, such as PET (melting point 258° C.), PEN (melting point 269° C.), PE (melting point 135° C.), PP (melting point 163° C.), polystyrene (melting point 230° C.), polyvinyl chloride (melting point 180° C.), polyvinylidene chloride (melting point 212° C.), or TAC (melting point 290° C.) The PET is particularly preferred from the viewpoints of light transmittance, workability, etc. The conductive sheet such as the first conductive sheet 10A or the second conductive sheet 10B used in the conductive sheet stack 54 is required to be transparent, and therefore the first transparent substrate 12A and the second transparent substrate 12B preferably have a high transparency.

### [Silver Salt Emulsion Layer]

The silver salt emulsion layer for forming the first conductive part 14A in the first conductive sheet 10A (the first large lattices 68A, the first connections 72A, the first auxiliary patterns 66A, the second auxiliary patterns 66B, and the like) and the second conductive part 14B in the second conductive sheet 10B (the second large lattices 68B, the second connections 72B, the third auxiliary patterns 66C, and the like) contains a silver salt and a binder and may further contain a solvent and an additive such as a dye.

The silver salt used in this embodiment may be an inorganic silver salt such as a silver halide or an organic silver salt such as silver acetate. In this embodiment, the silver halide is preferred because of its excellent light sensing property.

The applied silver amount (the amount of the applied silver salt in the silver density) of the silver salt emulsion layer is preferably 1 to 30 g/m², more preferably 1 to 25 g/m², further preferably 5 to 20 g/m². When the applied silver amount is within this range, the resultant conductive sheet can exhibit a desired surface resistance.

Examples of the binders used in this embodiment include gelatins, polyvinyl alcohols (PVA), polyvinyl pyrolidones (PVP), polysaccharides such as starches, celluloses and derivatives thereof, polyethylene oxides, polyvinylamines, chitosans, polylysines, polyacrylic acids, polyalginic acids, polyhyaluronic acids, and carboxycelluloses. The binders show a neutral, anionic, or cationic property depending on the ionicity of a functional group.

In this embodiment, the amount of the binder in the silver salt emulsion layer is not particularly limited, and may be appropriately selected to obtain sufficient dispersion and adhesion properties. The volume ratio of silver/binder in the silver salt emulsion layer is preferably 1/4 or more, more preferably 1/2 or more. The silver/binder volume ratio is preferably 100/1 or less, more preferably 50/1 or less. Particularly, the silver/binder volume ratio is further preferably 1/1 to 4/1, most preferably 1/1 to 3/1. As long as the silver/binder volume ratio of the silver salt emulsion layer falls within this range, the resistance variation can be reduced even under various applied silver amount, whereby the conductive sheet can be produced with a uniform surface resistance. The silver/binder volume ratio can be obtained by converting the silver halide/binder weight ratio of the material to the silver/binder weight ratio, and by further converting the silver/binder weight ratio to the silver/binder volume ratio.

### <Solvent>

The solvent used for forming the silver salt emulsion layer is not particularly limited, and examples thereof include water, organic solvents (e.g. alcohols such as methanol, ketones such as acetone, amides such as formamide, sulfoxides such as dimethyl sulfoxide, esters such as ethyl acetate, ethers), ionic liquids, and mixtures thereof.

In this embodiment, the ratio of the solvent to the total of the silver salt, the binder, and the like in the silver salt emulsion layer is 30% to 90% by mass, preferably 50% to 80% by mass.

### <Other Additives>

The additives used in this embodiment are not particularly limited, and may be preferably selected from known additives.

### [Other Layers]

A protective layer (not shown) may be formed on the silver salt emulsion layer. The protective layer used in this embodiment contains a binder such as a gelatin or a high-molecular polymer, and is disposed on the photosensitive silver salt emulsion layer to improve the scratch prevention or mechanical property. The thickness of the protective layer is preferably 0.5 μm or less. The method of applying or forming the protective layer is not particularly limited, and may be appropriately selected from known applying or forming methods. In addition, an undercoat layer or the like may be formed below the silver salt emulsion layer.

The steps for producing the first conductive sheet 10A and the second conductive sheet 10B will be described below.

### [Exposure]

In this embodiment, the first conductive part 14A and the second conductive part 14B may be formed in a printing process, and may be formed by exposure and development treatments, etc. in another process. Thus, a photosensitive material having the first transparent substrate 12A or the second transparent substrate 12B and thereon the silver salt-containing layer or a photosensitive material coated with a photopolymer for photolithography is subjected to the exposure treatment. An electromagnetic wave may be used in the exposure. For example, the electromagnetic wave may be a light such as a visible light or an ultraviolet light, or a radiation ray such as an X-ray. The exposure may be carried out using a light source having a wavelength distribution or a specific wavelength.

The exposure is preferably carried out using a glass mask method or a laser lithography pattern exposure method.

### [Development Treatment]

In this embodiment, the emulsion layer is subjected to the development treatment after the exposure. Common development treatment technologies for photographic silver salt films, photographic papers, print engraving films, emulsion masks for photomasking, and the like may be used in the present invention. The developer used in the development treatment is not particularly limited, and may be a PQ developer, an MQ developer, an MAA developer, etc. Examples of commercially available developers usable in the present invention include CN-16, CR-56, CP45X, FD-3, and PAPITOL available from FUJIFILM Corporation, C-41, E-6, RA-4, D-19, and D-72 available from Eastman Kodak Company, and developers contained in kits thereof. The developer may be a lith developer.

In the present invention, the development process may include a fixation treatment for removing the silver salt in the unexposed areas to stabilize the material. Fixation treatment technologies for photographic silver salt films, photographic papers, print engraving films, emulsion masks for photomasking, and the like may be used in the present invention.

In the fixation treatment, the fixation temperature is preferably about 20° C. to 50° C., more preferably 25° C. to 45° C. The fixation time is preferably 5 seconds to 1 minute, more preferably 7 to 50 seconds. The amount of the fixer used is preferably 600 ml/m² or less, more preferably 500 ml/m² or less, particularly preferably 300 ml/m² or less, per 1 m² of the photosensitive material treated.

The developed and fixed photosensitive material is preferably subjected to a water washing treatment or a stabilization treatment. The amount of water used in the water washing or stabilization treatment is generally 20 L or less, and may be 3 L or less, per 1 m² of the photosensitive material. The water amount may be 0, and thus the photosensitive material may be washed with storage water.

The ratio of the metallic silver contained in the exposed areas after the development to the silver contained in the areas before the exposure is preferably 50% or more, more preferably 80% or more by mass. When the ratio is 50% or more by mass, a high conductivity can be achieved.

In this embodiment, the tone (gradation) obtained by the development is preferably more than 4.0, though not particularly restrictive. When the tone is more than 4.0 after the development, the conductivity of the conductive metal portion can be increased while maintaining the high transmittance of the light-transmitting portion. For example, the tone of 4.0 or more can be obtained by doping with rhodium or iridium ion.

The conductive sheet is obtained by the above steps. The surface resistance of the resultant conductive sheet is preferably within a range of 0.1 to 100 ohm/sq. The lower limit is preferably 1 ohm/sq or more, 3 ohm/sq or more, 5 ohm/sq or more, or 10 ohm/sq. The upper limit is preferably 70 ohm/sq or less or 50 ohm/sq or less. When the surface resistance is controlled within this range, the position detection can be performed even in a large touch panel having an area of 10 cm×10 cm or more. The conductive sheet may be subjected to a calender treatment after the development treatment to obtain a desired surface resistance.

### [Physical Development Treatment and Plating Treatment]

In this embodiment, to increase the conductivity of the metallic silver portion formed by the above exposure and development treatments, conductive metal particles may be deposited thereon by a physical development treatment and/or a plating treatment. In the present invention, the conductive metal particles may be deposited on the metallic silver portion by only one of the physical development and plating treatments or by the combination of the treatments. The metallic silver portion, subjected to the physical development treatment and/or the plating treatment in this manner, is also referred to as the conductive metal portion.

In this embodiment, the physical development is such a process that metal ions such as silver ions are reduced by a reducing agent, whereby metal particles are deposited on a metal or metal compound core. Such physical development has been used in the fields of instant B & W film, instant slide film, printing plate production, etc., and the technologies can be used in the present invention.

The physical development may be carried out at the same time as the above development treatment after the exposure, and may be carried out after the development treatment separately.

In this embodiment, the plating treatment may contain electroless plating (such as chemical reduction plating or displacement plating). Known electroless plating technologies for printed circuit boards, etc. may be used in this embodiment. The electroless plating is preferably electroless copper plating.

### [Oxidation Treatment]

In this embodiment, the metallic silver portion formed by the development treatment or the conductive metal portion formed by the physical development treatment and/or the plating treatment is preferably subjected to an oxidation treatment. For example, by the oxidation treatment, a small amount of a metal deposited on the light-transmitting portion can be removed, so that the transmittance of the light-transmitting portion can be increased to approximately 100%.

### [Conductive Metal Portion]

In this embodiment, the line width of the conductive metal portion (a line width of the thin metal wire 16) may be selected from a range of 30 μm or less. Particularly in the touch panel, the line width of the thin metal wire 16 is preferably 0.1 μm or more and 15 μm or less, more preferably 1 μm or more and 9 μm or less, further preferably 2 μm or more and 7 μm or less. When the line width is less than the lower limit, the conductive metal portion has an insufficient conductivity, whereby the touch panel has an insufficient detection sensitivity. On the other hand, when the line width is more than the upper limit, moire is significantly generated due to the conductive metal portion, and the touch panel has a poor visibility. When the line width is within the above range, the moire of the conductive metal portion is improved, and the visibility is remarkably improved. The line distance (the distance between the sides facing each other in the small lattice 70) is preferably 30 μm or more and 500 μm or less, more preferably 50 μm or more and 400 μm or less, most preferably 100 μm or more and 350 μm or less. The conductive metal portion may have a part with a line width of more than 200 μm for the purpose of ground connection, etc.

In this embodiment, the opening ratio of the conductive metal portion is preferably 85% or more, more preferably 90% or more, most preferably 95% or more, in view of the visible light transmittance. The opening ratio is the ratio of the light-transmitting portions other than the conductive portions to the entire surface of the first conductive part 14A or the second conductive part 14B. For example, a square lattice having a line width of 15 μm and a pitch of 300 μm has an opening ratio of 90%.

### [Light-Transmitting Portion]

In this embodiment, the light-transmitting portion is a portion having light transmittance other than the conductive metal portions in the first conductive sheet 10A and the second conductive sheet 10B. The transmittance of the light-transmitting portion, which is herein a minimum transmittance value in a wavelength region of 380 to 780 nm obtained neglecting the light absorption and reflection of the first transparent substrate 12A and the second transparent substrate 12B, is 90% or more, preferably 95% or more, more preferably 97% or more, further preferably 98% or more, most preferably 99% or more.

### [First Conductive Sheet 10A and Second Conductive Sheet 10B]

In the first conductive sheet 10A and the second conductive sheet 10B of this embodiment, the thicknesses of the first transparent substrate 12A and the second transparent substrate 12B are preferably 5 to 350 μm, and further preferably 30 to 150 μm. When the thicknesses are within the range of 5 to 350 μm, a desired visible light transmittance can be obtained, and the substrates can be easily handled.

The thickness of the metallic silver portion formed on the first transparent substrate 12A or the second transparent substrate 12B may be appropriately selected by controlling the thickness of the coating liquid for the silver salt-containing layer applied to the first transparent substrate 12A or the second transparent substrate 12B. The thickness of the metallic silver portion may be selected within a range of 0.001 to 0.2 mm, and is preferably 30 μm or less, more preferably 20 μm or less, further preferably 0.01 to 9 μm, most preferably 0.05 to 5 μm. The metallic silver portion is preferably formed in a patterned shape. The metallic silver portion may have a monolayer structure or a multilayer structure containing two or more layers. When the metallic silver portion has a patterned multilayer structure containing two or more layers, the layers may have different wavelength color sensitivities. In this case, different patterns can be formed in the layers by using exposure lights with different wavelengths.

In the touch panel, the conductive metal portion preferably has a smaller thickness. As the thickness is reduced, the viewing angle and visibility of the display panel are improved. Thus, the thickness of the layer of the conductive metal on the conductive metal portion is preferably less than 9 μm, more preferably 0.1 μm or more but less than 5 μm, further preferably 0.1 μm or more but less than 3 μm.

In this embodiment, the thickness of the metallic silver portion can be controlled by changing the coating thickness of the silver salt-containing layer, and the thickness of the conductive metal particle layer can be controlled in the physical development treatment and/or the plating treatment, whereby the first conductive sheet 10A and the second conductive sheet 10B having a thickness of less than 5 μm (preferably less than 3 μm) can be easily produced.

The plating or the like is not necessarily carried out in the method for producing the first conductive sheet 10A and the second conductive sheet 10B of this embodiment. This is because the desired surface resistance can be obtained by controlling the applied silver amount and the silver/binder volume ratio of the silver salt emulsion layer in the method. The calender treatment or the like may be carried out if necessary.

(Film Hardening Treatment after Development Treatment)

It is preferred that after the silver salt emulsion layer is developed, the resultant is immersed in a hardener and thus subjected to a film hardening treatment. Examples of the hardeners include dialdehydes (such as glutaraldehyde, adipaldehyde, and 2,3-dihydroxy-1,4-dioxane) and boric acid, described in Japanese Laid-Open Patent Publication No. 02-141279.

An additional functional layer such as an antireflection layer or a hard coat layer may be formed in the conductive sheet stack.

In the touch panel 50, the conductive metal portion preferably has a smaller thickness. As the thickness is reduced, the viewing angle and visibility of the display panel 58 are improved. Thus, the thickness of the layer of the conductive metal on the conductive metal portion is preferably less than 9 μm, more preferably 0.1 μm or more but less than 5 μm, further preferably 0.1 μm or more but less than 3 μm.

In this embodiment, the thickness of the metallic silver portion can be controlled by changing the coating thickness of the silver salt-containing layer, and the thickness of the conductive metal particle layer can be controlled in the physical development treatment and/or the plating treatment, whereby the conductive sheet having a thickness of less than 5 μm (preferably less than 3 μm) can be easily produced.

The plating or the like is not necessarily carried out in the conductive sheet production method of this embodiment. This is because the desired surface resistance can be obtained by controlling the applied silver amount and the silver/binder volume ratio of the silver salt emulsion layer in the method. The calender treatment or the like may be carried out if necessary. An additional functional layer such as an antireflection layer or a hard coat layer may be formed in the conductive sheet stack.

### [Calender Treatment]

The developed metallic silver portion may be smoothened by a calender treatment. The conductivity of the metallic silver portion can be significantly increased by the calender treatment. The calender treatment may be carried out using a calender roll unit. The calender roll unit generally has a pair of rolls.

The roll used in the calender treatment may be composed of a metal or a plastic (such as an epoxy, polyimide, polyamide, or polyimide-amide). Particularly in a case where the photosensitive material has the emulsion layer on both sides, it is preferably treated with a pair of the metal rolls. In a case where the photosensitive material has the emulsion layer only on one side, it may be treated with the combination of the metal roll and the plastic roll in view of wrinkling prevention. The upper limit of the line pressure is preferably 1960 N/cm (200 kgf/cm, corresponding to a surface pressure of 699.4 kgf/cm²) or more, more preferably 2940 N/cm (300 kgf/cm, corresponding to a surface pressure of 935.8 kgf/cm²) or more. The upper limit of the line pressure is 6880 N/cm (700 kgf/cm) or less.

The smoothing treatment such as the calender treatment is preferably carried out at a temperature of 10° C. (without temperature control) to 100° C. Though the preferred treatment temperature range depends on the density and shape of the metal mesh or metal wiring pattern, the type of the binder, etc., the temperature is more preferably 10° C. (without temperature control) to 50° C. in general.

The present invention may be appropriately combined with technologies described in the following patent publications and international patent pamphlets shown in Tables 1 and 2. “Japanese Laid-Open Patent”, “Publication No.”, “Pamphlet No.”, etc. are omitted therein.

TABLE 1

| | | | | |
|---|---|---|---|---|
| 2004-221564 | 2004-221565 | 2007-200922 | 2006-352073 | 2007-129205 |
| 2007-235115 | 2007-207987 | 2006-012935 | 2006-010795 | 2006-228469 |
| 2006-332459 | 2009-21153 | 2007-226215 | 2006-261315 | 2007-072171 |
| 2007-102200 | 2006-228473 | 2006-269795 | 2006-269795 | 2006-324203 |
| 2006-228478 | 2006-228836 | 2007-009326 | 2006-336090 | 2006-336099 |
| 2006-348351 | 2007-270321 | 2007-270322 | 2007-201378 | 2007-335729 |
| 2007-134439 | 2007-149760 | 2007-208133 | 2007-178915 | 2007-334325 |
| 2007-310091 | 2007-116137 | 2007-088219 | 2007-207883 | 2007-013130 |
| 2005-302508 | 2008-218784 | 2008-227350 | 2008-227351 | 2008-244067 |
| 2008-267814 | 2008-270405 | 2008-277675 | 2008-277676 | 2008-282840 |
| 2008-283029 | 2008-288305 | 2008-288419 | 2008-300720 | 2008-300721 |
| 2009-4213 | 2009-10001 | 2009-16526 | 2009-21334 | 2009-26933 |
| 2008-147507 | 2008-159770 | 2008-159771 | 2008-171568 | 2008-198388 |
| 2008-218096 | 2008-218264 | 2008-224916 | 2008-235224 | 2008-235467 |
| 2008-241987 | 2008-251274 | 2008-251275 | 2008-252046 | 2008-277428 |

TABLE 2

| | | | | |
|---|---|---|---|---|
| 2006/001461 | 2006/088059 | 2006/098333 | 2006/098336 | 2006/098338 |
| 2006/098335 | 2006/098334 | 2007/001008 | | |

### EXAMPLES

The present invention will be described more specifically below with reference to Examples. Materials, amounts, ratios, treatment contents, treatment procedures, and the like, used in Examples, may be appropriately changed without departing from the scope of the present invention. The following specific examples are therefore to be considered in all respects as illustrative and not restrictive.

### First Example

In First Example, in Examples 1 to 4 and Comparative Example 1, the visibility of the conductive sheet stack 54 was evaluated. The properties, measurement results, and evaluation results of Examples 1 to 4 and Comparative Example 1 are shown in Table 3.

### Examples 1 to 4 and Comparative Example 1

### Photosensitive Silver Halide Material

An emulsion containing an aqueous medium, a gelatin, and silver iodobromochloride particles was prepared. The amount of the gelatin was 10.0 g per 150 g of Ag, and the silver iodobromochloride particles had an I content of 0.2 mol %, a Br content of 40 mol %, and an average spherical equivalent diameter of 0.1 μm.

K₃Rh₂Br₉ and K₂IrCl₆ were added to the emulsion at a concentration of 10⁻⁷ (mol/mol-silver) to dope the silver bromide particles with Rh and Ir ions. Na₂PdCl₄ was further added to the emulsion, and the resultant emulsion was subjected to gold-sulfur sensitization using chlorauric acid and sodium thiosulfate. The emulsion and a gelatin hardening agent were applied to a transparent substrate composed of a polyethylene terephthalate (PET). The amount of the applied silver was 10 g/m², and the Ag/gelatin volume ratio was 2/1.

The PET support had a width of 30 cm, and the emulsion was applied thereto into a width of 25 cm and a length of 20 m. The both end portions having a width of 3 cm were cut off to obtain a roll photosensitive silver halide material having a width of 24 cm.

### (Exposure)

An A4 (210 mm×297 mm) sized area of the first transparent substrate 12A was exposed in the pattern of the first conductive sheet 10A shown in FIGS. 2 and 4, and an A4 sized area of the second transparent substrate 12B was exposed in the pattern of the second conductive sheet 10B shown in FIGS. 2 and 5. The exposure was carried out using a parallel light from a light source of a high-pressure mercury lamp and patterned photomasks.

### (Development Treatment)

Formulation of 1 L of developer

| | |
|---|---|
| Hydroquinone | 20 g |
| Sodium sulfite | 50 g |
| Potassium carbonate | 40 g |
| Ethylenediaminetetraacetic acid | 2 g |
| Potassium bromide | 3 g |
| Polyethylene glycol 2000 | 1 g |
| Potassium hydroxide | 4 g |
| pH | Controlled at 10.3 |

Formulation of 1 L of fixer

| | | |
|---|---|---|
| Ammonium thiosulfate solution (75%) | 300 | ml |
| Ammonium sulfite monohydrate | 25 | g |
| 1,3-Diaminopropanetetraacetic acid | 8 | g |
| Acetic acid | 5 | g |
| Aqueous ammonia (27%) | 1 | g |

| | |
|---|---|
| pH | Controlled at 6.2 |

The exposed photosensitive material was treated with the above treatment agents using an automatic processor FG-710PTS manufactured by FUJIFILM Corporation under the following conditions. A development treatment was carried out at 35° C. for 30 seconds, a fixation treatment was carried out at 34° C. for 23 seconds, and then a water washing treatment was carried out for 20 seconds at a water flow rate of 5 L/min.

In Examples 1 to 4, the second auxiliary patterns 66B were formed in the blank areas 100 between the first large lattices 68A. In Comparative Example 1, the second auxiliary patterns 66B were not formed.

In Examples 1 to 4 and Comparative Example 1, the following properties were measured, and the visibility was evaluated.

### (Measurement Items)

The difference (%) between the light shielding ratio of the first large lattices 68A and the light shielding ratio of the overlaps of the second large lattices 68B and the second auxiliary patterns 66B.
{The light shielding ratio of the second auxiliary patterns 66B/the light shielding ratio of the first large lattices 68A}×100(%)

### (Visibility Evaluation)

In Examples 1 to 4 and Comparative Example 1, the first conductive sheet 10A was stacked on the second conductive sheet 10B to produce the conductive sheet stack 54. The conductive sheet stack 54 was attached to the display screen 58a of the display device 30 to form the touch panel 50. The touch panel 50 was fixed to a turntable, and the display device 30 was operated to display a white color. Whether a thickened line or a black point was formed or not on the touch panel 50 and whether the boundaries between the first large lattices 68A and the second large lattices 68B in the touch panel 50 were visible or not were observed by the naked eye.

TABLE 3

| | | | [Light | |
|---|---|---|---|---|
| | | | shielding | |
| | | Light shielding | ratio of | |
| | | ratio difference | second | |
| | | between first | auxiliary | |
| | | large lattices | patterns/light | |
| | | and overlaps of | shielding | |
| | | second large | ratio of | |
| | | lattices and | first large | |
| | Second | second auxiliary | lattices] × | |
| | auxiliary | patterns | 100 | |
| | pattern | (%) | (%) | Visibility |
| Comparative | Not | — | — | Poor |
| Example 1 | formed | | | |
| Example 1 | Formed | 20 | 50 | Good |
| Example 2 | Formed | 10 | 50 | Good |
| Example 3 | Formed | 5 | 50 | Excellent |
| Example 4 | Formed | 5 | 25 | Excellent |

As shown in Table 3, the conductive sheet stack 54 of Comparative Example 1 had a deteriorated visibility since the second auxiliary patterns 66B were not formed.

In contrast, the conductive sheet stacks 54 of Examples 1 to 4 had satisfactory visibilities since the second auxiliary patterns 66B were formed, the light shielding ratio difference (between the first large lattices 68A and the overlaps of the second large lattices 68B and the second auxiliary patterns 66B) was 20% or less, and the light shielding ratio of the second auxiliary patterns 66B was 50% or less of that of the first large lattices 68A.

### Second Example

In Second Example, the visibilities of Samples 1 to 49 were evaluated. With respect to the visibility, the visual finding difficulty of the thin metal wires and transmittance were evaluated. The properties and evaluation results of Samples 1 to 49 are shown in Tables 4 and 5.

### <Sample 1>

The photosensitive silver halide material was prepared in the same manner as Example 1 in First Example, and the photosensitive silver halide material was exposed and developed, whereby the first conductive sheet 10A and the second conductive sheet 10B of Sample 1 were produced. In Sample 1, the thin metal wires had a line width of 7 μm and a line pitch of 70 μm.

### <Samples 2 to 7>

The first conductive sheets 10A and the second conductive sheets 10B of Samples 2, 3, 4, 5, 6, and 7 were produced in the same manner as Sample 1 except that the thin metal wires had line pitches of 100, 200, 300, 400, 500, and 600 μm respectively.

### <Sample 8>

The first conductive sheet 10A and the second conductive sheet 10B of Sample 8 were produced in the same manner as Sample 1 except that the thin metal wires had a line width of 6 μm.

### <Samples 9 to 14>

The first conductive sheets 10A and the second conductive sheets 10B of Samples 9, 10, 11, 12, 13, and 14 were produced in the same manner as Sample 8 except that the thin metal wires had line pitches of 100, 200, 300, 400, 500, and 600 μm respectively.

### <Sample 15>

The first conductive sheet 10A and the second conductive sheet 10B of Sample 15 were produced in the same manner as Sample 1 except that the thin metal wires had a line width of 5 μm.

### <Samples 16 to 21>

The first conductive sheets 10A and the second conductive sheets 10B of Samples 16, 17, 18, 19, 20, and 21 were produced in the same manner as Sample 15 except that the thin metal wires had line pitches of 100, 200, 300, 400, 500, and 600 μm respectively.

### <Sample 22>

The first conductive sheet 10A and the second conductive sheet 10B of Sample 22 were produced in the same manner as Sample 1 except that the thin metal wires had a line width of 4 μm.

### <Samples 23 to 28>

The first conductive sheets 10A and the second conductive sheets 10B of Samples 23, 24, 25, 26, 27, and 28 were produced in the same manner as Sample 22 except that the thin metal wires had line pitches of 100, 200, 300, 400, 500, and 600 μm respectively.

### <Sample 29>

The first conductive sheet 10A and the second conductive sheet 10B of Sample 29 were produced in the same manner as Sample 1 except that the thin metal wires had a line width of 3 μm.

### <Samples 30 to 35>

The first conductive sheets 10A and the second conductive sheets 10B of Samples 30, 31, 32, 33, 34, and 35 were produced in the same manner as Sample 29 except that the thin metal wires had line pitches of 100, 200, 300, 400, 500, and 600 μm respectively.

### <Sample 36>

The first conductive sheet 10A and the second conductive sheet 10B of Sample 36 were produced in the same manner as Sample 1 except that the thin metal wires had a line width of 2 μm.

### <Samples 37 to 42>

The first conductive sheets 10A and the second conductive sheets 10B of Samples 37, 38, 39, 40, 41, and 42 were produced in the same manner as Sample 36 except that the thin metal wires had line pitches of 100, 200, 300, 400, 500, and 600 μm respectively.

### <Sample 43>

The first conductive sheet 10A and the second conductive sheet 10B of Sample 43 were produced in the same manner as Sample 1 except that the thin metal wires had a line width of 1 μm.

### <Samples 44 to 49>

The first conductive sheets 10A and the second conductive sheets 10B of Samples 44, 45, 46, 47, 48, and 49 were produced in the same manner as Sample 43 except that the thin metal wires had line pitches of 100, 200, 300, 400, 500, and 600 μm respectively.

### (Visibility Evaluation)

### <Visual Finding Difficulty of Thin Metal Wires>

In each of Samples 1 to 49, the first conductive sheet 10A was stacked on the second conductive sheet 10B to produce the conductive sheet stack 54. The conductive sheet stack 54 was attached to the display screen 58a of the display device 30 to form the touch panel 50. The touch panel 50 was fixed to a turntable, and the display device 30 was operated to display a white color. Whether a thickened line or a black point was formed or not on the touch panel 50 and whether the boundaries between the conductive patterns in the touch panel 50 were visible or not were observed by the naked eye.

The touch panel 50 was evaluated as “Excellent” when the thickened line, the black point, and the conductive pattern boundary were less visible, as “Good” when one of the thickened line, the black point, and the conductive pattern boundary was highly visible, as “Fair” when two of the thickened line, the black point, and the conductive pattern boundary was highly visible, or as “Poor” when all of the thickened line, the black point, and the conductive pattern boundary was highly visible.

### <Transmittance>

The transmittance of the conductive sheet stack 54 was measured by a spectrophotometer. The conductive sheet stack 54 was evaluated as “Excellent” when the transmittance was 90% or more, as “Good” when the transmittance was at least 85% but less than 90%, as “Fair” when the transmittance was at least 80% but less than 85%, or as “Poor” when the transmittance was less than 80%.

TABLE 4

| | | | Visibility | |
|---|---|---|---|---|
| | | | Visual | |
| | Line width | Pitch of | finding | |
| | of thin | thin metal | difficulty | |
| | metal wire | wire | of thin | |
| | (μm) | (μm) | metal wire | Transmittance |
| Sample 1 | 7 | 70 | Good | Poor |
| Sample 2 | 7 | 100 | Good | Poor |
| Sample 3 | 7 | 200 | Good | Poor |
| Sample 4 | 7 | 300 | Excellent | Good |
| Sample 5 | 7 | 400 | Good | Excellent |
| Sample 6 | 7 | 500 | Poor | Good |
| Sample 7 | 7 | 600 | Poor | Good |
| Sample 8 | 6 | 70 | Good | Poor |
| Sample 9 | 6 | 100 | Good | Poor |
| Sample 10 | 6 | 200 | Good | Fair |
| Sample 11 | 6 | 300 | Excellent | Good |
| Sample 12 | 6 | 400 | Good | Excellent |
| Sample 13 | 6 | 500 | Fair | Good |
| Sample 14 | 6 | 600 | Poor | Good |
| Sample 15 | 5 | 70 | Good | Poor |
| Sample 16 | 5 | 100 | Good | Poor |
| Sample 17 | 5 | 200 | Excellent | Good |
| Sample 18 | 5 | 300 | Excellent | Excellent |
| Sample 19 | 5 | 400 | Good | Excellent |
| Sample 20 | 5 | 500 | Fair | Good |
| Sample 21 | 5 | 600 | Poor | Good |
| Sample 22 | 4 | 70 | Good | Poor |
| Sample 23 | 4 | 100 | Good | Poor |
| Sample 24 | 4 | 200 | Excellent | Good |
| Sample 25 | 4 | 300 | Excellent | Excellent |
| Sample 26 | 4 | 400 | Good | Excellent |
| Sample 27 | 4 | 500 | Fair | Good |
| Sample 28 | 4 | 600 | Poor | Good |

TABLE 5

| | | | Visibility | |
|---|---|---|---|---|
| | | | Visual | |
| | Line width | Pitch of | finding | |
| | of thin | thin metal | difficulty | |
| | metal wire | wire | of thin | |
| | (μm) | (μm) | metal wire | Transmittance |
| Sample 29 | 3 | 70 | Good | Poor |
| Sample 30 | 3 | 100 | Good | Fair |
| Sample 31 | 3 | 200 | Excellent | Good |
| Sample 32 | 3 | 300 | Excellent | Excellent |
| Sample 33 | 3 | 400 | Good | Excellent |
| Sample 34 | 3 | 500 | Fair | Good |
| Sample 35 | 3 | 600 | Poor | Good |
| Sample 36 | 2 | 70 | Good | Fair |
| Sample 37 | 2 | 100 | Good | Good |
| Sample 38 | 2 | 200 | Excellent | Excellent |
| Sample 39 | 2 | 300 | Excellent | Excellent |
| Sample 40 | 2 | 400 | Good | Excellent |
| Sample 41 | 2 | 500 | Fair | Good |
| Sample 42 | 2 | 600 | Poor | Good |
| Sample 43 | 1 | 70 | Good | Good |
| Sample 44 | 1 | 100 | Good | Good |
| Sample 45 | 1 | 200 | Excellent | Excellent |
| Sample 46 | 1 | 300 | Excellent | Excellent |
| Sample 47 | 1 | 400 | Good | Excellent |
| Sample 48 | 1 | 500 | Fair | Good |
| Sample 49 | 1 | 600 | Poor | Good |

As shown in Tables 4 and 5, both of visual finding difficulty of the thin metal wires and transmittance were satisfactory in Samples 4, 5, 11, and 12 (the thin metal wires having a line width of 6 μm or more and 7 μm or less and a line pitch of 300 μm or more and 400 μm or less), Samples 17 to 19, 24 to 26, and 31 to 33 (the thin metal wires having a line width of 3 μm or more and 5 μm or less and a line pitch of 200 μm or more and 400 μm or less), Samples 37 to 40 (the thin metal wires having a line width of 2 μm and a line pitch of 100 μm or more and 400 μm or less), and Samples 43 to 47 (the thin metal wires having a line width of 1 μm and a line pitch of 70 μm or more and to 400 μm or less).

Samples 4 and 5 (the thin metal wires having a line width of more than 6 μm but at most 7 μm and a line pitch of 300 μm or more and to 400 μm or less) and Samples 10 to 13, 17 to 20, 24 to 27, 31 to 34, 38 to 41, and 45 to 48 (the thin metal wires having a line width of 6 μm or less and a line pitch of 200 to 500 μm) exhibited preferred results.

Samples 4, 5, 11, and 12 (the thin metal wires having a line width of more than 5 μm but at most 7 μm and a line pitch of 300 μm or more and 400 μm or less) and Samples 17 to 19, 24 to 26, 31 to 33, 38 to 40, and 45 to 47 (the thin metal wires having a line width of 5 μm or less and a line pitch of 200 to 400 μm) exhibited particularly preferred results.

It is to be understood that the conductive sheet and the touch panel of the present invention are not limited to the above embodiments, and various changes and modifications may be made therein without departing from the scope of the present invention.

1. A conductive sheet, which is used on a display panel of a display device, comprising a first conductive part disposed closer to an input operation surface and a second conductive part disposed closer to the display panel, wherein the first conductive part and the second conductive part overlap with each other,
the first conductive part contains a plurality of first conductive patterns composed of thin metal wires, the first conductive patterns being arranged in one direction and each connected to a plurality of first electrodes,
the second conductive part contains a plurality of second conductive patterns composed of the thin metal wires, the second conductive patterns being arranged in a direction perpendicular to the one direction of the first conductive patterns and each connected to a plurality of second electrodes,
at least one of the first conductive part and the second conductive part contain dummy electrodes composed of the thin metal wires disposed between the first electrodes and the second electrodes, and
the first conductive part contains additional dummy electrodes composed of the thin metal wires disposed in positions corresponding to the second electrodes.

2. The conductive sheet according to claim 1, wherein the difference in light shielding ratio between the first electrodes and overlaps of the second electrodes and the additional dummy electrodes is 20% or less.

3. The conductive sheet according to claim 1, wherein the difference in light shielding ratio between the first electrodes and overlaps of the second electrodes and the additional dummy electrodes is 10% or less.

4. The conductive sheet according to claim 1, wherein a light shielding ratio of the additional dummy electrodes is 50% or less of a light shielding ratio of the first electrodes.

5. The conductive sheet according to claim 1, wherein a light shielding ratio of the additional dummy electrodes is 25% or less of a light shielding ratio of the first electrodes.

6. The conductive sheet according to according to claim 1, wherein the additional dummy electrodes composed of the thin metal wires disposed in the positions corresponding to the second electrodes and the second electrodes in the second conductive part are combined to form lattice patterns.

7. The conductive sheet according to according to claim 1, wherein the second electrodes are composed of the thin metal wires arranged in a mesh pattern.

8. The conductive sheet according to claim 7, wherein
the first electrodes each contain a combination of a plurality of first small lattices,
the second electrodes each contain a combination of a plurality of second small lattices larger than the first small lattices,
the second small lattices each have a length component, and
a length of the length component is a real-number multiple of a side length of the first small lattice.

9. The conductive sheet according to claim 1, wherein the additional dummy electrodes disposed in the positions corresponding to the second electrodes are composed of the thin metal wires having a straight line shape.

10. The conductive sheet according to claim 9, wherein
the first electrodes each contain a combination of a plurality of first small lattices, and
a length of the thin metal wire having the straight line shape in the additional dummy electrodes is a real-number multiple of a side length of the first small lattice.

11. The conductive sheet according to claim 1, wherein the additional dummy electrodes disposed in the positions corresponding to the second electrodes are composed of the thin metal wires arranged in a mesh pattern.

12. The conductive sheet according to claim 11, wherein
the first electrodes each contain a combination of a plurality of first small lattices,
the additional dummy electrodes each contain a combination of a plurality of second small lattices larger than the first small lattices,
the second small lattices each have a length component, and
the length of the length component is a real-number multiple of a side length of the first small lattice.

13. The conductive sheet according to claim 1, further comprising a substrate, wherein
the first conductive part and the second conductive part are arranged facing each other with the substrate interposed therebetween.

14. The conductive sheet according to claim 13, wherein
the first conductive part is formed on one main surface of the substrate, and
the second conductive part is formed on the other main surface of the substrate.

15. The conductive sheet according to claim 1, further comprising a substrate, wherein
the first conductive part and the second conductive part are arranged facing each other with the substrate interposed therebetween,
the first electrodes and the second electrodes each have a mesh pattern,
auxiliary patterns of the additional dummy electrodes composed of the thin metal wires are disposed between the first electrodes in an area corresponding to the second electrodes,
the second electrodes are arranged adjacent to the first electrodes as viewed from above,
the second electrodes overlap with the auxiliary patterns to form combined patterns, and
the combined patterns each contain a combination of mesh shapes.

16. The conductive sheet according to claim 15, wherein
the first electrodes each contain a first large lattice containing a combination of a plurality of first small lattices,
the second electrodes each contain a second large lattice containing a combination of a plurality of second small lattices larger than the first small lattices, and
the combined patterns each contain a combination of two or more first small lattices.

17. The conductive sheet according to claim 1, wherein an occupation area of the first conductive patterns is larger than an occupation area of the second conductive patterns.

18. The conductive sheet according to claim 17, wherein the thin metal wires have a line width of 6 μm or less and a line pitch of 200 μm or more and 500 μm or less, or alternatively the thin metal wires have a line width of more than 6 μm but at most 7 μm and a line pitch of 300 μm or more and 400 μm or less.

19. The conductive sheet according to claim 17, wherein the thin metal wires have a line width of 5 μm or less and a line pitch of 200 μm or more and 400 μm or less, or alternatively the thin metal wires have a line width of more than 5 μm but at most 7 μm and a line pitch of 300 μm or more and 400 μm or less.

20. The conductive sheet according to claim 17, wherein if the first conductive patterns have an occupation area A1 and the second conductive patterns have an occupation area A2, the conductive sheet satisfies the condition of 1<A1/A2≦20.

21. The conductive sheet according to claim 17, wherein if the first conductive patterns have an occupation area A1 and the second conductive patterns have an occupation area A2, the conductive sheet satisfies the condition of 1<A1/A2≦10.

22. The conductive sheet according to claim 17, wherein if the first conductive patterns have an occupation area A1 and the second conductive patterns have an occupation area A2, the conductive sheet satisfies the condition of 2≦A1/A2≦10.

23. A touch panel comprising a conductive sheet, which is used on a display panel of a display device, wherein
the conductive sheet has a first conductive part disposed closer to an input operation surface and a second conductive part disposed closer to the display panel,
the first conductive part and the second conductive part overlap with each other,
the first conductive part contains a plurality of first conductive patterns, the first conductive patterns being arranged in one direction and each connected to a plurality of first electrodes,
the second conductive part contains a plurality of second conductive patterns, the second conductive patterns being arranged in a direction perpendicular to the one direction of the first conductive patterns and each connected to a plurality of second electrodes,
at least one of the first conductive part and the second conductive part contain dummy electrodes disposed between the first electrodes and the second electrodes, and
the first conductive part contains additional dummy electrodes disposed in positions corresponding to the second electrodes.
